(19) United States
(12) Patent Application Publication
(10) Pub. No.: US 2023/0095585 A1
(43) Pub. Date: Mar. 30, 2023

(54) PHOTOSENSITIVE COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Noriaki SATO, Haibara-gun (JP); Yasuhiro SAWAMURA, Haibara-gun (JP); Hiroaki IDEI, Haibara-gun (JP); Satomu ISHII, Haibara-gun (JP)

(73) Assignee: FUJIFILM Corporation, Tokyo (JP)

(21) Appl. No.: 17/994,766

(22) Filed: Nov. 28, 2022

Related U.S. Application Data
(63) Continuation of application No. PCT/JP2021/019490, filed on May 24, 2021.

(30) Foreign Application Priority Data
May 28, 2020 (JP) 2020-093013

(51) Int. Cl. G03F 7/031; G03F 7/00; G02B 5/22

(52) U.S. Cl. CPC G03F 7/031; G03F 7/0007; G02B 5/223

(57) ABSTRACT

Provided are a photosensitive composition including a colorant A, a photopolymerization initiator B, a polymerizable compound C, and a compound D which is a salt of an anion and a di- or higher valent cation having a formula weight or molecular weight of 1000 or less and has a specific absorbance of 5 or less, the specific absorbance being at a maximum absorption wavelength in a wavelength range of 400 to 700 nm; a film formed of the photosensitive composition; and a color filter, a solid-state imaging element, and an image display device, which includes the film.

### CROSS-REFERENCE TO RELATED APPLICATIONS

This application is a Continuation of PCT International Application No. PCT/JP2021/019490 filed on May 24, 2021, which claims priority under 35 U.S.C. § 119(a) to Japanese Patent Application No. 2020-093013 filed on May 28, 2020. Each of the above application(s) is hereby expressly incorporated by reference, in its entirety, into the present application.

### BACKGROUND OF THE INVENTION

### 1. Field of the Invention

The present invention relates to a photosensitive composition including a colorant. The present invention further relates to a film formed of the photosensitive composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Pixels of each color of the color filter are manufactured, for example, by forming a pattern by a photolithography method using a photosensitive composition including a colorant. For example, JP2016-133604A discloses that a pattern is formed by a photolithography method using a photosensitive composition containing an acidic dye, a binder resin, a predetermined ionic compound having a maximum value of a molar absorption coefficient s in a visible light region of 0 to 3000, and an organic solvent to form a pixel of a color filter.

### SUMMARY OF THE INVENTION

In recent years, a pixel size of a color filter or the like has been miniaturized. However, in forming the pixel by a photolithography method using the photosensitive composition, as the pixel size to be formed is finer, the pixel obtained after development tends to be more likely to be chipped.

In addition, from intensive studies with regard to the photosensitive composition disclosed in JP2016-133604A, the present inventor has found that, even with the photosensitive composition, the pixel obtained after development is more likely to be chipped, and there is room for improvement.

Therefore, an object of the present invention is to provide a photosensitive composition that a pixel in which chipping is suppressed can be formed. Another object of the present invention is to provide a film formed of the photosensitive composition, a color filter, a solid-state imaging element, and an image display device.

According to the studies conducted by the present inventors, it has been found that the above-described object can be achieved by adopting the following configuration, thereby leading to the completion of the present invention. Therefore, the present invention provides the following.
<1> A photosensitive composition comprising:
a colorant A;
a photopolymerization initiator B;
a polymerizable compound C; and
a compound D which is a salt of an anion and a di- or higher valent cation having a formula weight or molecular weight of 1000 or less and has a specific absorbance of 5 or less, the specific absorbance being represented by Expression (A_{λ}) at a maximum absorption wavelength in a wavelength range of 400 to 700 nm,

E¹=A¹/(c¹×l¹) . . . (A_{λ})

in Expression (A_{λ}), E¹ represents the specific absorbance of the compound D at the maximum absorption wavelength in the wavelength range of 400 to 700 nm, A¹ represents an absorbance of the compound D at the maximum absorption wavelength in the wavelength range of 400 to 700 nm, l¹ represents a cell length in units of cm, and c¹ represents a concentration of the compound D in a solution in units of mg/ml.
<2> The photosensitive composition according to <1>,
in which the cation of the compound D is a di- or higher valent metal cation.
<3> The photosensitive composition according to <2>,
in which the di- or higher valent metal cation is a magnesium cation, an aluminum cation, a calcium cation, a scandium cation, a titanium cation, a vanadium cation, a chromium cation, a manganese cation, an iron cation, a cobalt cation, a nickel cation, a copper cation, a zinc cation, a gallium cation, a strontium cation, a barium cation, a hafnium cation, a radium cation, or a cation of a rare earth element.
<4> The photosensitive composition according to <1>,
in which the cation of the compound D is a magnesium cation, a calcium cation, a copper cation, a zinc cation, a strontium cation, a lanthanum cation, a cerium cation, or a neodymium cation.
<5> The photosensitive composition according to any one of <1> to <4>,
in which the anion of the compound D has at least one selected from a fluorine atom or a sulfur atom.
<6> The photosensitive composition according to any one of <1> to <5>,
in which a pKa of a conjugate acid of the anion of the compound D is 0 or less.
<7> The photosensitive composition according to any one of <1> to <6>,
in which the anion of the compound D is a sulfonate anion having a fluorine atom, a sulfate anion, a sulfonimide anion, or a sulfomethide anion.
<8> The photosensitive composition according to any one of <1> to <7>,
in which the anion of the compound D is an anion represented by Formula (1) or Formula (2),

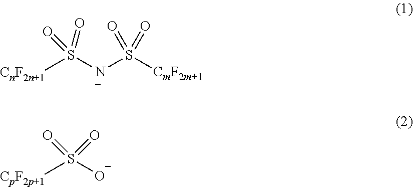

in the formulae, n, m, and p each independently represent an integer of 1 or more.
<9> The photosensitive composition according to any one of <1> to <8>,
in which an amount of the compound D dissolved in 100 g of cyclohexanone at 25° C. is 0.1 g or more.
<10> The photosensitive composition according to any one of <1> to <9>,
in which the compound D is included in an amount of 1 to 5 mass % in a total solid content of the photosensitive composition.
<11> The photosensitive composition according to any one of <1> to <10>,
in which the colorant A includes a dye.
<12> The photosensitive composition according to <11>,
in which the dye includes a compound having a coloring agent structure selected from a xanthene coloring agent structure, a triarylmethane coloring agent structure, a cyanine coloring agent structure, a squarylium coloring agent structure, and an anthraquinone coloring agent structure.
<13> The photosensitive composition according to <11> or <12>,
in which the dye includes at least one selected from a cyan dye, a magenta dye, or a yellow dye.
<14> A film formed of the photosensitive composition according to any one of <1> to <13>.
<15> A color filter comprising:
the film according to <14>.
<16> A solid-state imaging element comprising:
the film according to <14>.
<17> An image display device comprising:
the film according to <14>.

According to the present invention, it is to provide a photosensitive composition that a pixel in which chipping is suppressed can be formed. According to the present invention, it is also possible to provide a film formed of the photosensitive composition, a color filter, a solid-state imaging element, and an image display device.

### DESCRIPTION OF THE PREFERRED EMBODIMENTS

Hereinafter, the details of the present invention will be described.

In the present specification. “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a structural formula, Me represents a methyl group, Et represents an ethyl group, Pr represents a propyl group. Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a coloring material which is hardly dissolved in a solvent.

In the present specification, a dye means a coloring material which is easily soluble in a solvent.

In the present specification, a cation means an atom having a positive charge or an atomic group having a positive charge.

In the present specification, an anion means an atom having a negative charge or an atomic group having a negative charge.

In the present specification, symbols (for example, A, B, C, D, and the like) added before or after the name are terms used to distinguish the components, and the type of the component, the number of components, and the superiority or inferiority of the components are not limited.

In the present specification, a term “step” is not only an independent step, but also includes a step which is not clearly distinguished from other steps in a case where an intended action of the step is obtained.

<Photosensitive Composition>

A photosensitive composition according to an embodiment of the present invention includes a colorant A, a photopolymerization initiator B, a polymerizable compound C, and a compound D which is a salt of an anion and a di- or higher valent cation having a formula weight or molecular weight of 1000 or less and has a specific absorbance of 5 or less, the specific absorbance being represented by an expression (A_{λ}) at a maximum absorption wavelength in a wavelength range of 400 to 700 nm.

With the photosensitive composition according to the embodiment of the present invention, it is possible to form a pixel in which chipping is suppressed. Although a detailed reason for obtaining such an effect is unknown, since the photosensitive composition according to the embodiment of the present invention includes the above-described compound D, it is presumed that, during film formation, a film-forming component such as the polymerizable compound C can be pseudo-crosslinked by the above-described compound D. Therefore, with the photosensitive composition according to the embodiment of the present invention, a strong film can be formed by exposure, and as a result, it is presumed that, in a case of removing a non-exposed portion by development, it is possible to suppress chipping of the film in the exposed portion.

The photosensitive composition according to the embodiment of the present invention can be preferably used as a photosensitive composition for a color filter. Specifically, the photosensitive composition according to the embodiment of the present invention can be preferably used as a photosensitive composition for forming a colored pixel of a color filter. Examples of the colored pixel include a red pixel, a blue pixel, a green pixel, a yellow pixel, a cyan pixel, and a magenta pixel. In addition, the photosensitive composition according to the embodiment of the present invention can also be suitably used for a pixel configuration described in WO2019/102887A. Hereinafter, each of the components used in the photosensitive composition according to the embodiment of the present invention will be described.

<<Colorant A>>

The photosensitive composition according to the embodiment of the present invention contains a colorant A (hereinafter, also referred to as a colorant). Examples of the colorant include a pigment and a dye. The colorant included in the photosensitive composition according to the embodiment of the present invention preferably includes a dye. Compared to a photosensitive composition using only a pigment as the colorant, the photosensitive composition using a colorant including a dye tends to cause chipping of the pixel during development in a case where the pixel is formed by a photolithography method, but according to the present invention, even in a case where the colorant including a dye is used, it is possible to form a pixel in which the chipping is suppressed. Therefore, the effects of the present invention are particularly remarkable in a case where the dye is used. In addition, in the photosensitive composition according to the embodiment of the present invention, only the dye may be used as the colorant, but from the reason that generation of development residue can be further suppressed, it is preferable to use a pigment and a dye in combination.

(Dye)

The type of the dye is not limited. As the dye, a known dye can be used. Examples thereof include a red dye, a blue, dye, a green dye, a cyan dye, a magenta dye, and a yellow dye. Examples of one aspect thereof include an aspect in which at least one selected from a cyan dye, a magenta dye, or a yellow dye is used.

As the dye, a compound having a coloring agent structure selected from a triarylmethane coloring agent structure, a xanthene coloring agent structure, an anthraquinone coloring agent structure, a cyanine coloring agent structure, a squarylium coloring agent structure, a quinophthalone coloring agent structure, a phthalocyanine coloring agent structure, a subphthalocyanine coloring agent structure, an azo coloring agent structure, a pyrazorotriazole coloring agent structure, a dipyrromethene coloring agent structure, an isoindoline coloring agent structure, a thiazole coloring agent structure, a benzoimidazolone coloring agent structure, a perinone coloring agent structure, a pyrrolopyrrole coloring agent structure, a diketopyrrolopyrrole coloring agent structure, a diimmonium coloring agent structure, a naphthalocyanine coloring agent structure, a rylene coloring agent structure, a dibenzofuranone coloring agent structure, a merocyanine coloring agent structure, a croconium coloring agent structure, or an oxonol coloring agent structure is preferable; a compound having a coloring agent structure selected from a triarylmethane coloring agent structure, a xanthene coloring agent structure, an anthraquinone coloring agent structure, a cyanine coloring agent structure, a squarylium coloring agent structure, a quinophthalone coloring agent structure, a phthalocyanine coloring agent structure, a subphthalocyanine coloring agent structure, an azo coloring agent structure, a thiazole coloring agent structure, a pyrazorotriazole coloring agent structure, or a dipyrromethene coloring agent structure is more preferable; a compound having a coloring agent structure selected from a triarylmethane coloring agent structure, a xanthene coloring agent structure, a cyanine coloring agent structure, or a squarylium coloring agent structure is still more preferable; a compound having a triarvlmethane coloring agent structure or a xanthene coloring agent structure is even more preferable; and a compound having a xanthene coloring agent structure is particularly preferable.

The amount of the dye dissolved in 100 g of propylene glycol methyl ether acetate at 25° C. is preferably 0.01 g or more, more preferably 0.5 g or more, and still more preferably 1 g or more.

The dye used in the present invention is preferably a dye having a chemical structure including a cation and an anion. Hereinafter, the dye having a chemical structure including a cation and an anion is also referred to as a dye A. In addition, the cation of the dye A is referred to as a “cation AX⁺”. In addition, the anion of the dye A is referred to as an “anion AZ⁻”.

In the dye A, the anion AZ⁻ may be present outside the molecule of the cation AX⁺. The fact that “the anion AZ⁻ is present outside the molecule of the cation AX⁺” refers to a state in which the anion AZ⁻ is not bonded to the cation AX⁺ through a covalent bond and exists as a structural unit independent of the cation AX⁺. Examples of the form of the dye A as described above include a salt. Hereinafter, the anion existing outside the molecule of the cation is also referred to as a counter anion. In the dye A, the anion AZ⁻ is preferably bonded to the cation AX⁺ through a covalent bond. That is, the form of the dye A is preferably an intramolecular salt (also referred to as an amphoteric ion).

Examples of the type of the anion AZ⁻ include a fluorine anion, a chlorine anion, a bromine anion, an iodine anion, a cyanide ion, a perchlorate anion, a carboxylate anion, a sulfonate anion, an anion including a phosphorus atom, an imide anion, a methide anion, a borate anion, and SbF₆⁻, and an imide anion, a methide anion, or a borate anion is preferable, an imide anion or a methide anion is more preferable, and from the reason that it has low nucleophilicity, an imide anion is still more preferable. As the imide anion, a bis(sulfonyl) imide anion is preferable. As the methide anion, a tris(sulfonyl) methide anion is preferable. Examples of the borate anion include a tetraarylborate anion, a tetracyanoborate anion, and a tetrafluoroborate anion.

Examples of the type of the cation AX⁺ include a cation having a xanthene coloring agent structure, a cation having a triarylmethane coloring agent structure, a cation having a cyanine coloring agent structure, and a cation having a squarylium coloring agent structure. The cation AX⁺ is preferably a cation having a xanthene coloring agent structure or a cation having a triarylmethane coloring agent structure, and from the reason that the effects of the present invention are likely to be obtained more remarkably, a cation having a xanthene coloring agent structure is more preferable.

Examples of a dye having the cation AX⁺ having a xanthene coloring agent structure include a compound represented by Formula (J).

Formula (J)

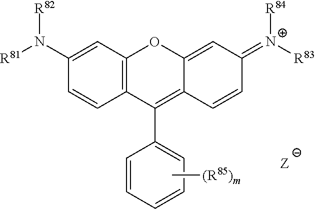

In Formula (J), R⁸¹, R⁸², R⁸³, and R⁸⁴ each independently represent a hydrogen atom or a substituent, R⁸⁵'s each independently represent a substituent, and m represents an integer of 0 to 5. Z represents a counter anion. In a case where Z is not present, at least one of R⁸¹, . . . , or R⁸⁵ includes an anion.

Examples of the substituent which can be adopted as R⁸¹ to R⁸⁵ in Formula (J) include groups mentioned in the substituent T described later and a polymerizable group. In Formula (J), R⁸¹ and R⁸², R⁸³ and R⁸⁴, and R⁸⁵'s in a case where m is 2 or more may be each independently bonded to each other to form a 5-membered, 6-membered, or 7-membered saturated ring or a 5-membered, 6-membered, or 7-membered unsaturated ring. Examples of the ring to be formed include a pyrrole ring, a furan ring, a thiophene ring, a pyrazole ring, an imidazole ring, a triazole ring, an oxazole ring, a thiazole ring, a pyrrolidine ring, a piperidine ring, a cyclopentene ring, a cyclohexene ring, a benzene ring, a pyridine ring, a pyrazine ring, and a pyridazine ring, and preferred examples thereof include a benzene ring and a pyridine ring. In a case where the ring to be formed is a group which can be further substituted, it may be substituted with the substituents described as R⁸¹ to R⁸⁵, and in a case of being substituted with two or more substituents, these substituents may be the same or different from each other.

In Formula (J), Z represents a counter anion. Examples of the counter anion include a fluorine anion, a chlorine anion, a bromine anion, an iodine anion, a cyanide ion, a perchlorate anion, a carboxylate anion, a sulfonate anion, an anion including a phosphorus atom, an imide anion, a methide anion, a borate anion, and SbF₆⁻, and an imide anion, a methide anion, or a borate anion is preferable, an imide anion or a methide anion is more preferable, and an imide anion is still more preferable. As the imide anion, a bis(sulfonyl) imide anion is preferable. As the methide anion, a tris(sulfonyl) methide anion is preferable. Examples of the borate anion include a tetraarylborate anion, a tetracyanoborate anion, and a tetrafluoroborate anion. The molecular weight of the counter anion is preferably 100 to 1000 and more preferably 200 to 500.

In Formula (J), in a case where at least one of R⁸¹, . . . , or R⁸⁵ includes an anion, as the anion, a carboxylate anion, a sulfonate anion, an anion including a phosphorus atom, an imide anion, a methide anion, or a borate anion is preferable, an imide anion, a methide anion, or a borate anion is more preferable, an imide anion or a methide anion is still more preferable, and an imide anion is particularly preferable. As the imide anion, a bis(sulfonyl) imide anion is preferable. As the methide anion, a tris(sulfonyl) methide anion is preferable. Specifically, it is preferable that at least one of R⁸¹, . . . , or R⁸⁵ is a group including a partial structure represented by Formula (AZ-1) or a group including a partial structure represented by Formula (AZ-2), and it is more preferable to be a group including a partial structure represented by Formula (AZ-1).

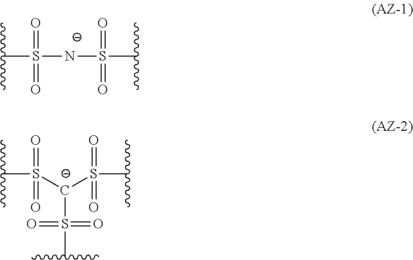 [SMILES: *S(=O)(=O)[N-]S(*)(=O)=O ; *S(=O)(=O)[C-](S(*)(=O)=O)S(*)(=O)=O]

The wavy line in the above formulae represents a bonding site with another atom or atomic group.

In a case where at least one of R⁸¹, . . . , or R⁸⁵ includes an anion, it is also preferable that at least one of R⁸¹, . . . , or R⁸⁵ is a structure substituted with Formula (P-1).

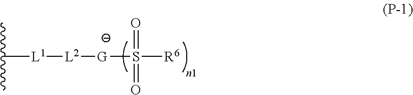

In Formula (P-1), L¹ represents a single bond or a divalent linking group, and a single bond is preferable. Examples of the divalent linking group represented by L¹ include an alkylene group having 1 to 6 carbon atoms, an arylene group having 6 to 12 carbon atoms, —O—, —S—, and a group consisting of a combination of these groups. L² represents —SO₂— or —CO—. G represents a carbon atom or a nitrogen atom. n1 represents 2 in a case where G is a carbon atom, and represents 1 in a case where G is a nitrogen atom. R⁶ represents an alkyl group including a fluorine atom or an aryl group including a fluorine atom. In a case where n1 is 2, two R⁶'s may be the same or different from each other. The alkyl group including a fluorine atom, represented by R⁶, preferably has 1 to 10 carbon atoms, more preferably has 1 to 6 carbon atoms, and still more preferably has 1 to 3 carbon atoms. The aryl group including a fluorine atom, represented by R⁶, preferably has 6 to 20 carbon atoms, more preferably has 6 to 14 carbon atoms, and still more preferably has 6 to 10 carbon atoms. The alkyl group including a fluorine atom and the aryl group including a fluorine atom may further have a substituent. Examples of the substituent include a substituent T group and a polymerizable group.

In addition, examples of the dye having the cation AX⁺ having a xanthene coloring agent structure include C. I. Acid Red 51, C. I. Acid Red 52, C. I. Acid Red 87, C. I. Acid Red 92, C. I. Acid Red 94, C. I. Acid Red 289, C. I. Acid Red 388, Rose bengal B (edible red No. 5), Acid Rhodamine G. C. I. Acid Violet 9, and C. I. Acid Violet 30.

Examples of a dye having the cation AX⁺ having a triarylmethane coloring agent structure include a compound represented by Formula (TP).

Formula (TP)

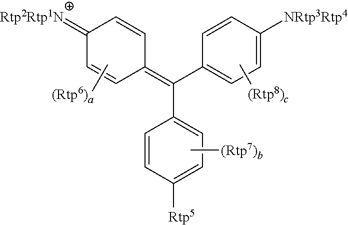

In Formula (TP), Rtp¹ to Rtp⁴ each independently represent a hydrogen atom, an alkyl group, or an aryl group. Rtp⁵ represents a hydrogen atom, an alkyl group, an aryl group, or NRtp⁹Rtp¹⁰ (Rtp⁹ and Rtp¹⁰ represent a hydrogen atom, an alkyl group, or an aryl group). Rtp⁶, Rtp⁷, and Rtp⁸ represent a substituent. a, b, and c represent an integer of 0 to 4. In a case where a, b, or c is 2 or more, Rtp⁶'s, Rtp⁷'s, or Rtp⁸'s may be connected to each other to form a ring. X represents a counter anion. In a case where Z is not present, at least one of Rtp¹, . . . , or Rtp⁸ includes an anion.

Rtp¹ to Rtp⁴ are preferably a hydrogen atom, a linear or branched alkyl group having 1 to 5 carbon atoms, or a phenyl group. Rtp⁵ is preferably a hydrogen atom or NRtp⁹Rtp¹⁰, and particularly preferably NRtp⁹Rtp¹⁰. Rtp⁹ and Rtp¹⁰ are preferably a hydrogen atom, a linear or branched alkyl group having 1 to 5 carbon atoms, or a phenyl group. Examples of the substituent represented by Rtp⁶, Rtp⁷, and Rtp⁸ include groups mentioned in the substituent T group described later and a polymerizable group.

In Formula (TP), Z represents a counter anion. In a case where Z is not present, at least one of Rtp¹, . . . , or Rtp⁸ includes an anion. Examples of the counter anion include the counter anions described in Formula (J). In addition, in Formula (TP), in a case where at least one of Rtp¹, . . . , or Rtp⁸ includes an anion, examples of the anion include the anions described in Formula (J).

(Substituent T Group)

Examples of the substituent T group include the following groups:

an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably an acyl group having 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having 1 to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureido group (preferably having 1 to 30 carbon atoms), a hydroxy group, a carboxyl group, a sulfo group, a phosphoric acid group, a carboxylic acid amide group, a sulfonic acid amide group, an imide acid group, a mercapto group, a halogen atom, a cyano group, an alkylsulfino group, an arylsulfino group, a hydrazino group, an imino group, and a heteroaryl group (preferably having 1 to 30 carbon atoms). In a case where the above-described groups can be further substituted, the groups may further have a substituent. Examples of the substituent include the groups described as the above-described substituent T group and a polymerizable group.

Examples of the polymerizable group include ethylenically unsaturated bond-containing groups such as a vinyl group, an allyl group, and a (meth)acryloyl group, an epoxy group, and an oxetanyl group.

From the reason that crosslinking density is high and it is easy to obtain a film having excellent various performances, the dye (preferably, the dye A) is preferably a compound having a polymerizable group.

In addition, from the reason that it is easy to reduce the generation of residues during development, the dye (preferably, the dye A) is also preferably a coloring agent multimer. The coloring agent multimer is a coloring agent compound having two or more coloring agent structures in one molecule, and it is preferable to have three or more coloring agent structures in one molecule. The upper limit is particularly not limited, but may be 100 or less. The coloring agent structures included in one molecule may be the same coloring agent structure or different coloring agent structures.

The weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less.

Examples of a structure of the coloring agent multimer include coloring agent multimers (A) to (D) described in paragraph Nos. 0047 to 0103 of WO2016/208524A. As the coloring agent multimer, a coloring agent multimer having a repeating unit represented by Formula (A) described later or a coloring agent multimer represented by Formula (D) described later is preferable. Hereinafter, the coloring agent multimer having a repeating unit represented by Formula (A) is also referred to as a coloring agent multimer (A). In addition, the coloring agent multimer represented by Formula (D) is also referred to as a coloring agent multimer (D).

The coloring agent multimer (A) preferably includes a repeating unit represented by Formula (A). The proportion of the repeating unit represented by Formula (A) is preferably 10 mass % or more, more preferably 20 mass % or more, still more preferably 30 mass % or more, and particularly preferably 50 mass % or more of all repeating units constituting the coloring agent multimer (A). The upper limit may be 100 mass % or less or 95 mass % or less.

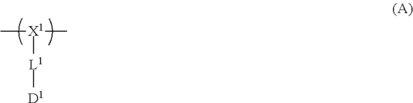

In Formula (A). X¹ represents a main chain of a repeating unit, L¹ represents a single bond or a divalent linking group, and D¹ represents a structure derived from a coloring agent compound.

Preferred examples of the main chain of a repeating unit, represented by X¹ in Formula (A), include a linking group formed by a polymerization reaction, and a main chain derived from a compound having a (meth)acryloyl group, a styrene group, a vinyl group, or an ether group. Specific examples of the linking group include linking groups represented by (XX-1) to (XX-30) described in paragraph No. 0049 of WO2016/208524A.

L¹ represents a single bond or a divalent linking group. Examples of the divalent linking group represented by L¹ include an alkylene group having 1 to 30 carbon atoms, an arylene group having 6 to 30 carbon atoms, a heterocyclic group, —CH═CH—, —O—, —S—, —C(═O)—, —COO—. —NR—, —CONR—, —OCO—, —SO—, —SO₂—, and a linking group formed by linking two or more these groups. Here, R represents a hydrogen atom, an alkyl group, an aryl group, or a heteroaryl group.

The alkylene group preferably has 1 to 30 carbon atoms. The upper limit is more preferably 25 or less and still more preferably 20 or less. The lower limit is more preferably 2 or more and still more preferably 3 or more. The alkylene group may be linear, branched, or cyclic. The alkylene group may have a substituent or may be unsubstituted. Examples of the substituent include the groups described in the substituent T group.

The arylene group preferably has 6 to 20 carbon atoms and more preferably has 6 to 12 carbon atoms. The arylene group may have a substituent or may be unsubstituted. Examples of the substituent include the groups described in the substituent T group.

The heterocyclic group is preferably a 5-membered ring or a 6-membered ring. A heteroatom included in the heterocyclic group is preferably an oxygen atom, a nitrogen atom, or a sulfur atom. The number of heteroatoms included in the heterocyclic group is preferably 1 to 3. The heterocyclic group may have a substituent or may be unsubstituted. Examples of the substituent include the groups described in the substituent T group.

Examples of the structure derived from a coloring agent compound, which is represented by D¹, include a residue obtained by removing one or more hydrogen atoms from a compound having a coloring agent structure selected from a triarylmethane coloring agent structure, a xanthene coloring agent structure, an anthraquinone coloring agent structure, a cyanine coloring agent structure, a squarylium coloring agent structure, a quinophthalone coloring agent structure, a phthalocyanine coloring agent structure, a subphthalocyanine coloring agent structure, an azo coloring agent structure, a pyrazorotriazole coloring agent structure, a dipyrromethene coloring agent structure, an isoindoline coloring agent structure, a thiazole coloring agent structure, a benzoimidazolone coloring agent structure, a perinone coloring agent structure, a pyrrolopyrrole coloring agent structure, a diketopyrrolopyrrole coloring agent structure, a diimmonium coloring agent structure, a naphthalocyanine coloring agent structure, a rylene coloring agent structure, a dibenzofuranone coloring agent structure, a merocyanine coloring agent structure, a croconium coloring agent structure, or an oxonol coloring agent structure. The structure derived from a coloring agent compound, which is represented by D¹, is preferably a structure derived from the compound represented by Formula (J) described above or a structure derived from the compound represented by Formula (TP) described above.

The coloring agent multimer (A) may include other repeating units in addition to the repeating unit represented by Formula (A). The other repeating units may include a functional group such as a polymerizable group and an acid group, or may not include these functional groups. Examples of the polymerizable group include ethylenically unsaturated bond-containing groups such as a vinyl group and a (meth)acryloyl group. Examples of the acid group include a carboxyl group, a sulfo group, and a phosphoric acid group.

The proportion of the repeating unit having a polymerizable group is preferably 0 to 50 mass % of all repeating units constituting the coloring agent multimer (A). The lower limit is preferably 1 mass % or more and more preferably 3 mass % or more. The upper limit is preferably 35 mass % or less and more preferably 30 mass % or less.

The proportion of the repeating unit having an acid group is preferably 0 to 50 mass % of all repeating units constituting the coloring agent multimer (A). The lower limit is preferably 1 mass % or more and more preferably 3 mass % or more. The upper limit is preferably 35 mass % or less and more preferably 30 mass % or less.

The coloring agent multimer (D) is preferably represented by Formula (D).

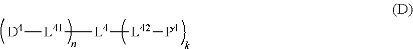

In Formula (D), L⁴ represents an (n+k)-valent linking group, L⁴¹ and L⁴² each independently represent a single bond or a divalent linking group, D⁴ represents a structure derived from a coloring agent compound, and P⁴ represents a substituent; n represents 2 to 15, k represents 0 to 13, and n+k is 2 to 15. n pieces of D⁴'s may be different from each other or the same. In a case where k is 2 or more, a plurality of P⁴'s may be the same as or different from each other.

n is preferably 2 to 14, more preferably 2 to 8, particularly preferably 2 to 7, and even more preferably 2 to 6. k is preferably 1 to 13, more preferably 1 to 10, still more preferably 1 to 8, particularly preferably 1 to 7, and even more preferably 1 to 6.

L⁴¹ and L⁴² each independently represent a single bond or a divalent linking group. The divalent linking group includes a group composed of 1 to 100 carbon atoms, 0 to 10 nitrogen atoms, 0 to 50 oxygen atoms, 1 to 200 hydrogen atoms, and 0 to 20 sulfur atoms, and may be unsubstituted or may further have a substituent. Specific examples of the divalent linking group include a group composed of one of the following structural units or a combination of two or more of the structural units.

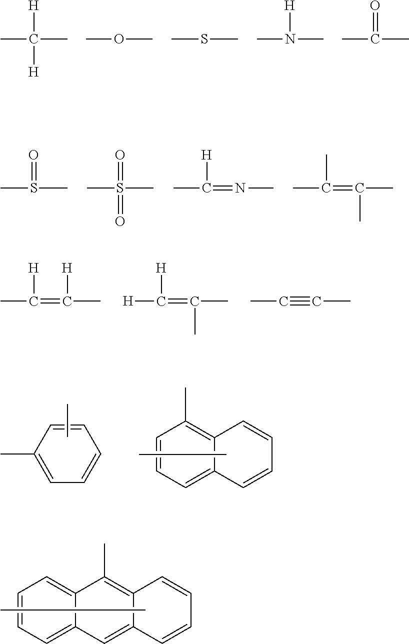

The (n+k)-valent linking group represented by L⁴ includes a group composed of 1 to 100 carbon atoms, 0 to 10 nitrogen atoms, 0 to 50 oxygen atoms, 1 to 200 hydrogen atoms, and 0 to 20 sulfur atoms. Examples of the (n+k)-valent linking group also include a group (which may form a ring structure) composed of the following structural unit or a combination of two or more the following structural units.

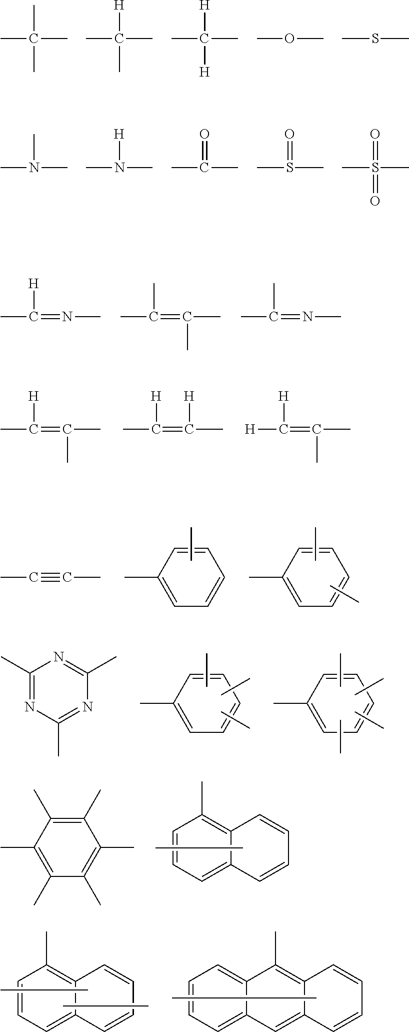

Specific examples of the (n+k)-valent linking group include linking groups described in paragraph No. 0084 of WO2016/208524A.

Examples of the structure derived from a coloring agent compound, which is represented by D⁴, include a residue obtained by removing one or more hydrogen atoms from a compound having a coloring agent structure selected from a triarylmethane coloring agent structure, a xanthene coloring agent structure, an anthraquinone coloring agent structure, a cyanine coloring agent structure, a squarylium coloring agent structure, a quinophthalone coloring agent structure, a phthalocyanine coloring agent structure, a subphthalocyanine coloring agent structure, an azo coloring agent structure, a pyrazorotriazole coloring agent structure, a dipyrromethene coloring agent structure, an isoindoline coloring agent structure, a thiazole coloring agent structure, a benzoimidazolone coloring agent structure, a perinone coloring agent structure, a pyrrolopyrrole coloring agent structure, a diketopyrrolopyrrole coloring agent structure, a diimmonium coloring agent structure, a naphthalocyanine coloring agent structure, a rylene coloring agent structure, a dibenzofuranone coloring agent structure, a merocyanine coloring agent structure, a croconium coloring agent structure, or an oxonol coloring agent structure. The structure derived from a coloring agent compound, which is represented by D⁴, is preferably a structure derived from the compound represented by Formula (J) described above or a structure derived from the compound represented by Formula (TP) described above.

Examples of the substituent represented by P⁴, include an acid group and a polymerizable group. In addition, the substituent represented by P⁴ may be a monovalent polymer chain having a repeating unit. The monovalent polymer chain having a repeating unit is preferably a monovalent polymer chain having a repeating unit derived from a vinyl compound. In a case where k is 2 or more, k pieces of P⁴'s may be the same or different from each other.

(Pigment)

The pigment may be either an inorganic pigment or an organic pigment, but is preferably an organic pigment. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

Examples of the organic pigment include a phthalocyanine pigment, a dioxazine pigment, a quinacridone pigment, an anthraquinone pigment, a perylene pigment, an azo pigment, an azomethine pigment, a diketopyrrolopyrrole pigment, a pyrrolopyrrole pigment, an isoindoline pigment, a quinophthalone pigment, a triarylmethane pigment, a xanthene pigment, a cyanine pigment, a quinoline pigment, and a pteridine pigment.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the photosensitive composition is good. In the present invention, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

The amount of the pigment dissolved in 100 g of propylene glycol methyl ether acetate at 25° C. is preferably less than 0.01 g, more preferably less than 0.005 g, and still more preferably less than 0.001 g.

Examples of the pigment include a yellow pigment, an orange pigment, a red pigment, a green pigment, a violet pigment, and a blue pigment. Specific examples of these pigments include the following pigments.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, an aluminum phthalocyanine compound having a phosphorus atom can also be used as the blue pigment. Specific examples thereof include the compounds described in paragraph Nos. 0022 to 0030 of JP2012-247591A and paragraph No. 0047 of JP2011-157478A.

In addition, as the yellow pigment, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), a compound represented by Formula (QP2), compounds described in KR10-2014-0034963A, compounds described in JP2017-095706A, compounds described in TW2019-20495A, compounds described in JP6607427B, compounds described in JP2020-033525A, compounds described in JP2020-033524A, compounds described in JP2020-033523A, compounds described in JP2020-033522A, compounds described in JP2020-033521A, compounds described in WO2020/045200A, compounds described in WO2020/045199A, and compounds described in WO2020/045197A can also be used. In addition, from the viewpoint of improving a color value, a multimerized compound of these compounds is also preferably used.

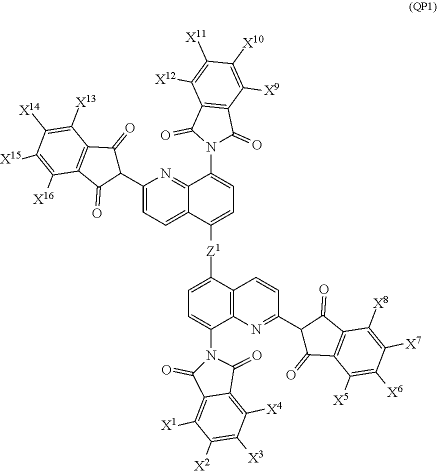

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

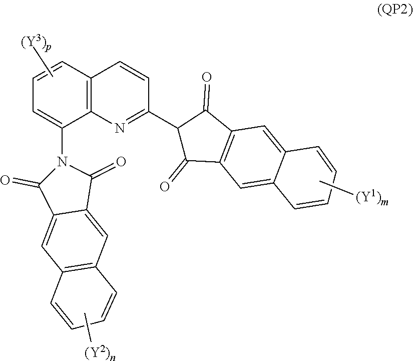

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

In addition, as the yellow pigment, an azobarbiturate nickel complex pigment having the following structure can also be used.

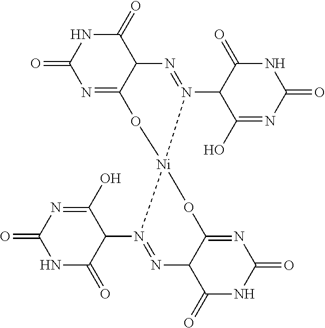

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red pigments described in JP6516119B, red pigments described in JP6525101B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In a case where the compound having a xanthene coloring agent structure (xanthene dye) or the compound having a triarylmethane coloring agent structure is used as the dye, as the pigment used in combination, at least one selected from a phthalocyanine pigment, a dioxazine pigment, or a triarvlmethane pigment is preferable. Specific examples thereof include C. I. Pigment Violet 23, C. I. Pigment Blue 15:3, 15:4, 15:6, and 16.

A content of the colorant in the total solid content of the photosensitive composition is preferably 40 mass % or more, more preferably 50 mass % or more, and still more preferably 60 mass % or more. The upper limit is preferably 80 mass % or less and more preferably 75 mass % or less.

In a case where the photosensitive composition according to the embodiment of the present invention includes a dye as the colorant, a content of the dye in the total solid content of the photosensitive composition is preferably 5 mass % or more, more preferably 8 mass % or more, still more preferably 10 mass % or more, and particularly preferably 15 mass % or more. The upper limit is preferably 80 mass % or less, more preferably 70 mass % or less, still more preferably 60 mass % or less, even more preferably 50 mass % or less, particularly preferably 40 mass % or less, and most preferably 30 mass % or less. In addition, the content of the dye in the colorant included in the photosensitive composition is preferably 5 mass % or more, more preferably 10 mass % or more, still more preferably 15 mass % or more, even more preferably 20 mass % or more, and particularly preferably 25 mass % or more. The upper limit may be 100 mass % or less, 90 mass % or less, 80 mass % or less, 70 mass % or less, 60 mass % or less, or 50 mass % or less.

In a case where the photosensitive composition according to the embodiment of the present invention includes a pigment as the colorant, a content of the pigment in the total solid content of the photosensitive composition is preferably 5 mass % or more, more preferably 10 mass % or more, still more preferably 15 mass % or more, even more preferably 20 mass % or more, and particularly preferably 25 mass % or more. The upper limit may be 100 mass % or less, 90 mass % or less, 80 mass % or less, 70 mass % or less, 60 mass % or less, or 50 mass % or less.

In a case where the photosensitive composition according to the embodiment of the present invention includes a pigment and a dye as the colorant, the content of the pigment is preferably 10 to 500 parts by mass with respect to 100 parts by mass of the dye. The lower limit is preferably 100 parts by mass or more, more preferably 130 parts by mass or more, and still more preferably 150 parts by mass or more. The upper limit is preferably 230 parts by mass or less and more preferably 200 parts by mass or less.

<<Photopolymerization Initiator B>>

The photosensitive composition according to the embodiment of the present invention includes a photopolymerization initiator B (hereinafter, also referred to as a photopolymerization initiator). The photopolymerization initiator is not particularly limited, and can be appropriately selected from known photopolymerization initiators. For example, a compound having photosensitivity to light in a range from an ultraviolet ray range to a visible light range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, and peroxide initiators described in JP2019-167313A, the contents of which are incorporated herein by reference.

Examples of a commercially available product of the α-hydroxyketone compound include Omnirad 184, Omnirad 1173, Omnirad 2959, and Omnirad 127 (all of which are manufactured by 1GM Resins B.V.). Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by 1GM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A. and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A. and compounds described in JP06636081B.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

As the photopolymerization initiator, an oxime compound in which a substituent having a hydroxy group is bonded to a carbazole skeleton can also be used. Examples of such a photopolymerization initiator include compounds described in WO2019088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

The oxime compound OX is preferably at least one selected from a compound represented by Formula (OX1) or a compound represented by Formula (OX2), and more preferably a compound represented by Formula (OX2).

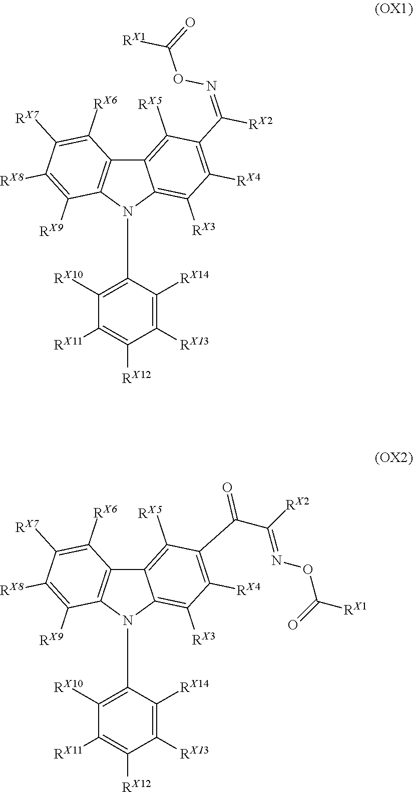

In the formula. R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,

R^{X3} to R^{X14} each independently represent a hydrogen atom or a substituent.

However, at least one of R^{X10}, . . . , or R^{X14} is an electron withdrawing group.

Examples of the electron withdrawing group include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

In the formulae, it is preferable that R^{X12} is an electron withdrawing group, and R^{X10}, R^{X11}. R^{X13}, and R^{X14} are hydrogen atoms.

Specific examples of the oxime compound OX include compounds described in paragraph Nos. 0083 to 0105 of JP4600600B.

Specific examples of the oxime compound which are preferably used in the present invention are shown below, but the present invention is not limited thereto.

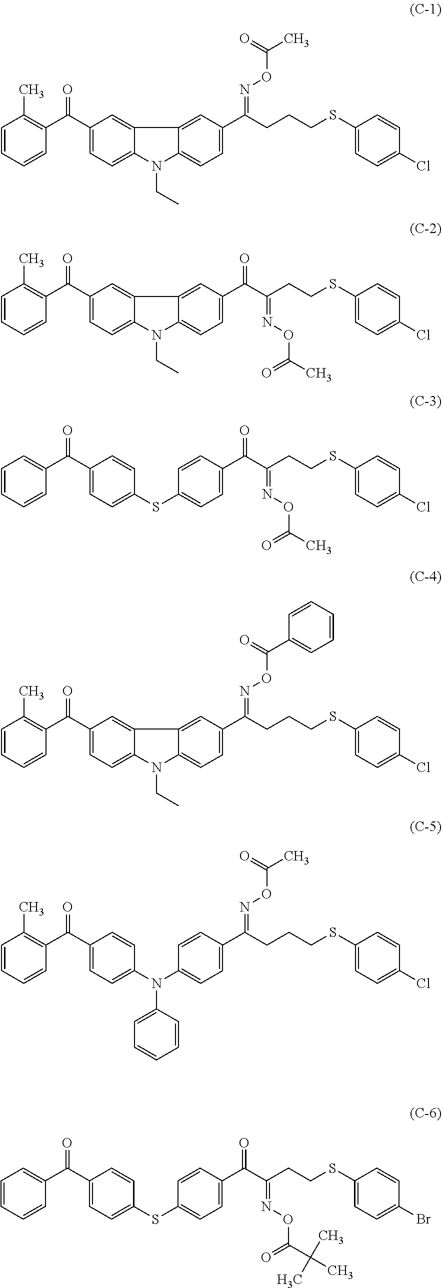 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

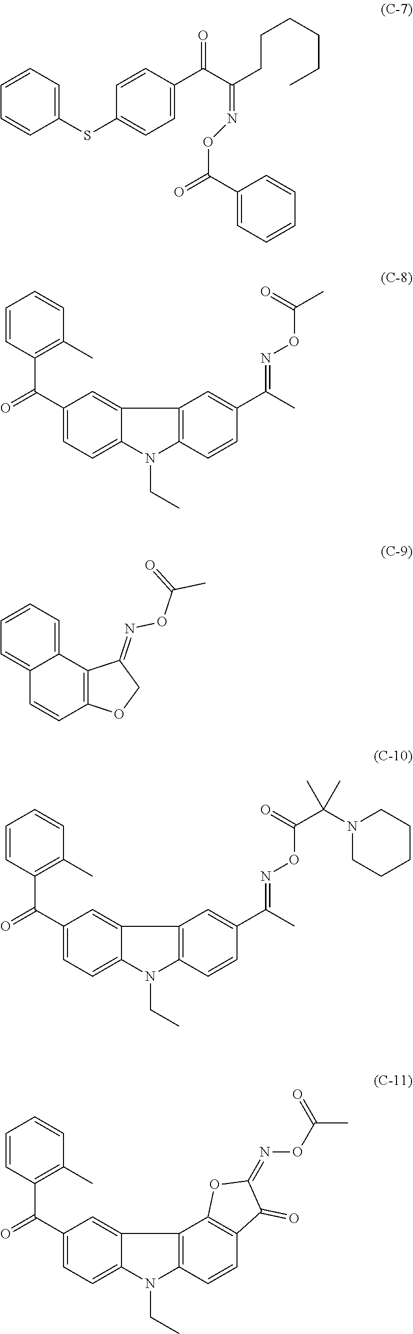 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

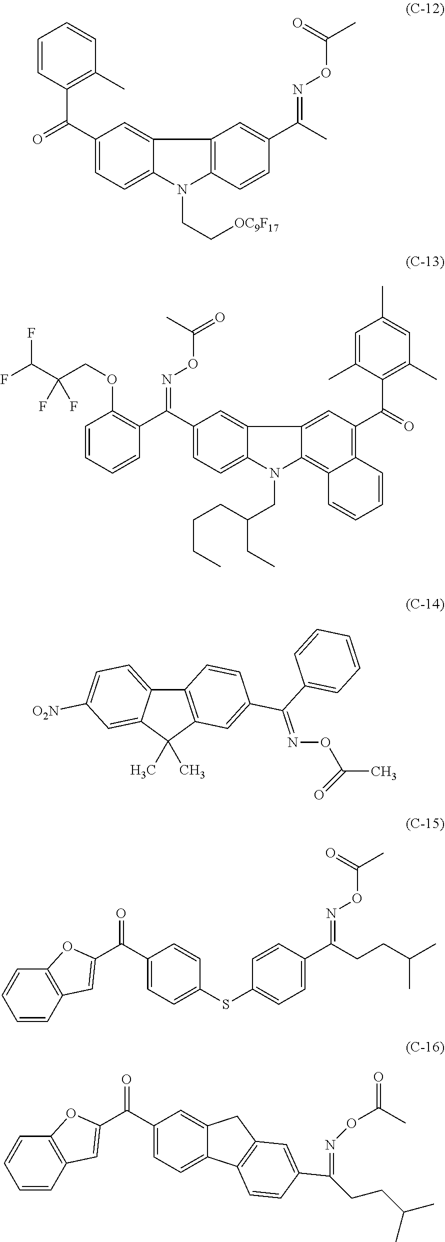

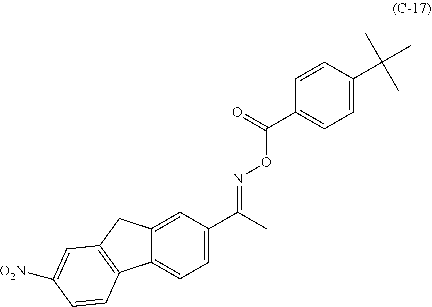 [SMILES: C/C(=N\OC(=O)c1ccc(C(C)(C)C)cc1)c1ccc2c(c1)Cc1cc([N+](=O)[O-])ccc1-2]

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a well-known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the photosensitive composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

In a case where the photosensitive composition according to the embodiment of the present invention contains a photopolymerization initiator, a content of the photopolymerization initiator in the total solid content of the photosensitive composition is preferably 0.1 to 30 mass %. The lower limit is preferably 0.5 mass % or more and more preferably 1 mass % or more. The upper limit is preferably 20 mass % or less and more preferably 15 mass % or less. In the photosensitive composition according to the embodiment of the present invention, the photopolymerization initiator may be used singly or in combination of two or more kinds thereof. In a case where two or more kinds thereof are used, the total amount thereof is preferably within the above-described range.

<<Polymerizable compound C>>

The photosensitive composition according to the embodiment of the present invention contains a polymerizable compound C (hereinafter, also referred to as a polymerizable compound). As the polymerizable compound, a known compound which is cross-linkable by a radical, an acid, or heat can be used. The polymerizable compound used in the present invention is preferably a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound having 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

As the polymerizable compound, it is also preferable to use a trifunctional (meth)acrylate compound such as trimethylolpropane tri(meth)acrylate, trimethylolpropane propylene oxide-modified tri(meth)acrylate, trimethylolpropane ethylene oxide-modified tn(meth)acrylate, isocyanuric acid ethylene oxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E. A-GLY-20E. A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a polymerizable compound having an acid group can also be used. Examples of the acid group include a carboxyl group, a sulfo group, and a phosphoric acid group, and a carboxyl group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

As the polymerizable compound, a polymerizable compound having a caprolactone structure can also be used. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

As the polymerizable compound, urethane acrylates described in JP1973-041708B (JP-S48-041708B), JP1976-037193A (JP-S51-037193A), JP1990-032293B (JP-H02-032293B), and JP1990-016765B (JP-H02-016765B); urethane compounds having an ethylene oxide skeleton described in JP1983-049860B (JP-S58-049860B), JP1981-017654B (JP-S56-017654B), JP1987-039417B (JP-S62-039417B), and JP1987-039418B (JP-S62-039418B); or polymerizable compounds having an amino structure or a sulfide structure in the molecule, described in JP1988-277653A (JP-S63-277653A), JP1988-260909A (JP-S63-260909A), and JP1989-105238A (JP-H01-105238A) can also be preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

A content of the polymerizable compound in the total solid content of the photosensitive composition is preferably 0.1 to 50 mass %. The lower limit is more preferably 0.5 mass % or more and still more preferably 1 mass % or more. The upper limit is more preferably 40 mass % or less and still more preferably 30 mass % or less. In the photosensitive composition according to the embodiment of the present invention, the polymerizable compound may be used singly or in combination of two or more kinds thereof. In a case where two or more kinds thereof are used, the total amount thereof is preferably within the above-described range.

<<Compound D>>

The photosensitive composition according to the embodiment of the present invention includes a compound D which is a salt of an anion and a di- or higher valent cation having a formula weight or molecular weight of 1000 or less and has a specific absorbance of 5 or less, the specific absorbance being represented by Expression (A_{λ}) at a maximum absorption wavelength in a wavelength range of 400 to 700 nm.

E¹=A¹/(c¹×l¹) . . . (A_{λ})

In Expression (A_{λ}), E¹ represents the specific absorbance of the compound D at the maximum absorption wavelength in the wavelength range of 400 to 700 nm,

A¹ represents an absorbance of the compound D at the maximum absorption wavelength in the wavelength range of 400 to 700 nm,

l¹ represents a cell length in units of cm, and

c¹ represents a concentration of the compound D in a solution in units of mg/ml.

The specific absorbance of the compound D, represented by Expression (A_{λ}), is 5 or less, preferably 3 or less and more preferably 1 or less. The specific absorbance represented by Expression (A_{λ}) is an indicator indicating the degree of absorption of the compound D with light in the visible range. As the specific absorbance represented by Expression (A_{λ}) is smaller, absorption of light in the visible range is lower. The lower limit of the specific absorbance is not limited. In a case where the lower limit of the specific absorbance is provided, the specific absorbance represented by Expression (A_{λ}) may be determined in a range of 0.001 or more.

The absorbance represented by “A¹” in Expression (A_{λ}) is measured by the following method. A measurement sample is prepared using the compound D and a solvent in which the compound D is sufficiently dissolved. In a case where the compound D has sufficient solubility in methanol, methanol is used as the solvent. In a case where the compound D does not have sufficient solubility in methanol, cyclohexanone is used as the solvent. The absorbance of the above-described measurement sample at 25° C. (room temperature) is measured using a cell having an optical path length of 1 cm.

A molecular weight of the compound D is preferably 200 to 5000. The upper limit is preferably 3000 or less, more preferably 2000 or less, and still more preferably 1500 or less. The lower limit is preferably 250 or more and more preferably 300 or more.

The amount of the compound D dissolved in 100 g of methanol at 25° C. is preferably 0.1 g or more, more preferably 0.5 g or more, and still more preferably 1 g or more.

The amount of the compound D dissolved in 100 g of cyclohexanone at 25° C. is preferably 0.1 g or more, more preferably 0.5 g or more, and still more preferably 1 g or more.

(Cation)

The valence of the cation in the compound D is 2 or more, preferably 2, 3, or 4, and from the reason that it is possible to form a pixel in which chipping is more suppressed, more preferably 2 or 3.

The formula weight or molecular weight of the cation in the compound D is 1000 or less, preferably 24 to 1000, and from the reason that it is possible to form a pixel in which chipping is more suppressed, more preferably 24 to 300, and still more preferably 24 to 150.

Examples of the type of the cation in the compound D include (1) a di- or higher valent metal cation and (2) a di- or higher valent cation having two or more cations selected from a carbocation, an ammonium cation, a phosphonium cation, and a sulfonium cation in one molecule. Among these, from the reason that it is possible to form a pixel in which chipping is more suppressed, a di- or higher valent metal cation is preferable.

As the di- or higher valent metal cation, a cation of an element selected from a third period element, a fourth period element, a fifth period element, a sixth period element, a seventh period element, and a rare earth element is preferable, and a cation of an element selected from a third period element, a fourth period element, a fifth period element, and a rare earth element is more preferable. Specifically, a magnesium cation, an aluminum cation, a calcium cation, a scandium cation, a titanium cation, a vanadium cation, a chromium cation, a manganese cation, an iron cation, a cobalt cation, a nickel cation, a copper cation, a zinc cation, a gallium cation, a strontium cation, a yttrium cation, a zirconium cation, a ruthenium cation, a rhodium cation, a palladium cation, an indium cation, a tin cation, a barium cation, a hafnium cation, a tantalum cation, a rhenium cation, an iridium cation, a platinum cation, or a cation of a rare earth element is preferable; a magnesium cation, an aluminum cation, a calcium cation, a scandium cation, a titanium cation, a vanadium cation, a chromium cation, a manganese cation, an iron cation, a cobalt cation, a nickel cation, a copper cation, a zinc cation, a gallium cation, a strontium cation, a barium cation, a hafnium cation, a radium cation, or a cation of a rare earth element is more preferable; a magnesium cation, an aluminum cation, a calcium cation, a scandium cation, a titanium cation, a vanadium cation, a chromium cation, a manganese cation, an iron cation, a cobalt cation, a nickel cation, a copper cation, a zinc cation, a gallium cation, a strontium cation, a barium cation, a hafnium cation, a radium cation, a lanthanum cation, a cerium cation, a praseodymium cation, a neodymium cation, a samarium cation, an europium cation, a gadolinium cation, a terbium cation, a thulium cation, a ytterbium cation, or a lutetium cation is still more preferable; and a magnesium cation, an aluminum cation, a calcium cation, a scandium cation, a titanium cation, a copper cation, a zinc cation, a gallium cation, a strontium cation, a barium cation, a hafnium cation, a lanthanum cation, a cerium cation, a neodymium cation, a samarium cation, an europium cation, or a gadolinium cation is particularly preferable. From the reason that the cation has a small ionic radius and is easily interacted with film-forming components such as the polymerizable compound C, a magnesium cation, a calcium cation, a copper cation, a zinc cation, a strontium cation, a lanthanum cation, a cerium cation, or a neodymium cation is most preferable.

Examples of the di- or higher valent cation other than the metal cation include a cation having a structure shown below.

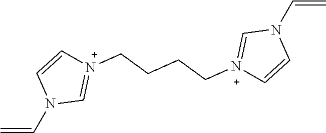 [SMILES: C=Cn1cc[n+](CCCC[n+]2ccn(C=C)c2)c1]

(Anion)

The valence of the anion in the compound D is preferably 1 to 4, more preferably 1 or 2, and from the reason that it is difficult to inhibit the interaction of the cation with the film-forming components and it is possible to form a pixel in which chipping is more suppressed, still more preferably 1.

Examples of the anion in the compound D include an imide anion, a methide anion, a borate anion, an anion including a phosphorus atom, a sulfonate anion, and a sulfate anion, and an imide anion, a methide anion, or a borate anion is preferable, an imide anion or a methide anion is more preferable, and an imide anion is still more preferable. In addition, the anion is preferably an anion having at least one selected from a fluorine atom or a sulfur atom, and more preferably an anion including each of a fluorine atom and a sulfur atom. As the anion having at least one selected from a fluorine atom or a sulfur atom, a sulfonate anion having a fluorine atom, a sulfate anion, a sulfonimide anion, or a sulfomethide anion is preferable, a sulfonimide anion is more preferable, and a fluoroalkylsulfonimide anion is still more preferable.

The pKa of the conjugate acid of the anion in the compound D is preferably 0 or less, more preferably −5 or less, still more preferably −8 or less, even more preferably −10 or less, and particularly preferably −10.5 or less. The lower limit is not particularly limited, but may be −20 or more or may be −18 or more. In a case where the pKa of the conjugate acid of the anion in the compound D is 0 or less, the anion in the compound D interacts with the colorant to further suppress the decomposition of the colorant by heating, whereby it is possible to form a film in which variation in spectral characteristics due to the heating is further suppressed. For example, the pKa of the conjugate acid can be measured by a method described in J. Org. Chem. 2011, 76, pp. 391 to 395.

A molecular weight of the anion in the compound D is preferably 80 to 1500, more preferably 150 to 1250, and still more preferably 200 to 1000.

Examples of the anion in the compound D include an anion having a partial structure represented by Formula (BZ-1), an anion having a partial structure represented by Formula (BZ-2), an anion represented by Formula (BZ-3), an anion represented by Formula (BZ-4), an anion represented by Formula (BZ-5), and a sulfate anion. Among these, an anion having a partial structure represented by Formula (BZ-1), an anion having a partial structure represented by Formula (BZ-2), and an anion represented by Formula (BZ-3), an anion represented by Formula (BZ-4), or a sulfate anion is preferable, an anion having a partial structure represented by Formula (BZ-1), an anion having a partial structure represented by Formula (BZ-2), an anion represented by Formula (BZ-4), or a sulfate anion is more preferable, an anion having a partial structure represented by Formula (BZ-1), an anion represented by Formula (BZ-4), or a sulfate anion is still more preferable, and an anion having a partial structure represented by Formula (BZ-1) is particularly preferable. The anion having a partial structure represented by Formula (BZ-1) is an imide anion, the anion having a partial structure represented by Formula (BZ-2) is a methide anion, the anion represented by Formula (BZ-3) is a borate anion, the anion represented by Formula (BZ-4) is a sulfonate anion, and the anion represented by Formula (BZ-5) is an anion including a phosphorus atom.

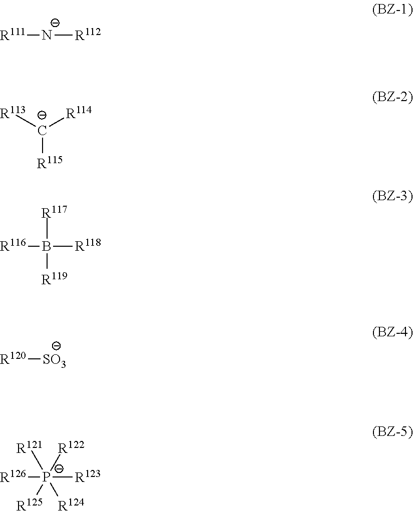

In Formula (BZ-1), R¹¹¹ and R¹¹² each independently represent —SO₂— or —CO—;

in Formula (BZ-2), R¹¹³ represents —SO₂— or —CO—, and R¹¹⁴ and R¹¹⁵ each independently represent —SO₂—, —CO—, or a cyano group;

in Formula (BZ-3), R¹¹⁶ to R¹¹⁹ each independently represent a halogen atom, an alkyl group, an aryl group, an alkoxy group, an aryloxy group, or a cyano group;

in Formula (BZ-4), R¹²⁰ represents a halogenated hydrocarbon group which may be linked by a linking group having a nitrogen atom or an oxygen atom; and

in Formula (BZ-5), R¹²¹ to R¹²⁶ each independently represent a halogen atom or a halogenated hydrocarbon group.

In Formula (BZ-1), it is preferable that at least one of R¹¹¹ or R¹¹² represents —SO₂—, and it is more preferable that both R¹¹¹ and R¹¹² represent —SO₂—.

At at least one terminal of R¹¹¹ or R¹¹², the anion having a partial structure represented by Formula (BZ-1) preferably has a halogen atom or an alkyl group (haloalkyl group) having a halogen atom as a substituent, and more preferably has a fluorine atom or an alkyl group (fluoroalkyl group) having a fluorine atom as a substituent. The number of carbon atoms in the fluoroalkyl group is preferably 1 to 10 and more preferably 1 to 6. The fluoroalkyl group is more preferably a perfluoroalkyl group.

In Formula (BZ-2), it is preferable that at least one of R¹¹³, R¹¹⁴, or R¹¹⁵ represents —SO₂—, it is more preferable that at least two of R¹¹³, R¹¹⁴, or R¹¹⁵ represent —SO₂—, it is still more preferable that all R¹¹³ to R¹¹⁵ represent —SO₂—, R¹¹³ and R¹¹⁵ represent —SO₂— and R¹¹⁴ represents —CO—, or R¹¹⁴ and R¹¹⁵ represent —SO₂— and R¹¹³ represents —CO—, and it is particularly preferable that all R¹¹³ to R¹¹⁵ represent —SO₂—.

At at least one terminal of R¹¹³, R¹¹⁴, or R¹¹⁵, the anion having a partial structure represented by Formula (BZ-2) preferably has a halogen atom or an alkyl group (haloalkyl group) having a halogen atom as a substituent, and more preferably has a fluorine atom or an alkyl group (fluoroalkyl group) having a fluorine atom as a substituent. In particular, at at least two terminals of R¹¹³, R¹¹⁴, or R¹¹⁵, it is preferable to have a halogen atom or a haloalkyl group, and it is more preferable to have a fluorine atom or a fluoroalkyl group. The number of carbon atoms in the fluoroalkyl group is preferably 1 to 10 and more preferably 1 to 6. The fluoroalkyl group is more preferably a perfluoroalkyl group.

In Formula (BZ-3), R¹¹⁶ to R¹¹⁹ each independently represent a halogen atom, an alkyl group, an aryl group, an alkoxy group, an aryloxy group, or a cyano group. The alkyl group, the aryl group, the alkoxy group, and the aryloxy group may have a substituent or may be unsubstituted. In a case of having a substituent, a halogen atom or an alkyl group substituted with a halogen atom is preferable, and a fluorine atom or an alkyl group substituted with a fluorine atom is more preferable. In Formula (BZ-3), it is preferable that at least one of R¹¹⁶, R¹¹⁷, R¹¹⁸, or R¹¹⁹ represents a cyano group, a halogen atom, an alkyl group having a halogen atom as a substituent, an aryl group having a halogen atom as a substituent, or an aryl group having an alkyl group substituted with a halogen atom as a substituent, and it is more preferable that all R¹¹⁶ to R¹¹⁹ represent a cyano group or an aryl group having a halogen atom (preferably, a fluorine atom) as a substituent.

In Formula (BZ-4), R¹²⁰ represents a halogenated hydrocarbon group which may be linked by a linking group having a nitrogen atom or an oxygen atom. The halogenated hydrocarbon group refers to a monovalent hydrocarbon group substituted with a halogen atom, and is preferably a monovalent hydrocarbon group substituted with a fluorine atom. Examples of the hydrocarbon group include an alkyl group and an aryl group. The monovalent hydrocarbon group substituted with a halogen atom may further have a substituent. Examples of the linking group having a nitrogen atom or an oxygen atom include —O—, —CO—, —COO—, and —CO—NH—. R¹²⁰ is preferably an alkyl group having a fluorine atom as a substituent (fluoroalkyl group). The number of carbon atoms in the fluoroalkyl group is preferably 1 to 10 and more preferably 1 to 6. The fluoroalkyl group is preferably a perfluoroalkyl group.

In Formula (BZ-5), R¹²¹ to R¹²⁶ each independently represent a halogen atom or a halogenated hydrocarbon group. The halogenated hydrocarbon group represented by R¹²¹ to R¹²⁶ is preferably an alkyl group having a halogen atom as a substituent, and more preferably an alkyl group having a fluorine atom as a substituent. The number of carbon atoms in the fluoroalkyl group is preferably 1 to 10 and more preferably 1 to 6. The fluoroalkyl group is preferably a perfluoroalkyl group.

The above-described anion having a partial structure represented by Formula (BZ-1) is preferably an anion represented by Formula (BZ1-1). In addition, the above-described anion having a partial structure represented by Formula (BZ-2) is preferably an anion represented by Formula (BZ2-1).

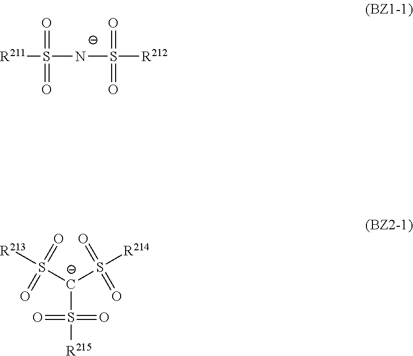

In Formula (BZ1-1), R²¹¹ and R²¹² each independently represent a halogen atom or an alkyl group, and in a case where R²¹¹ and R²¹² each independently represent an alkyl group, R²¹¹ and R²¹² may be bonded to each other to form a ring; and

in Formula (BZ2-1), R²¹³ to R²¹⁵ each independently represent a halogen atom or an alkyl group, in a case where R²¹³ and R²¹⁴ each independently represent an alkyl group, R²¹³ and R²¹⁴ may be bonded to each other to form a ring, in a case where R²¹⁴ and R²¹⁵ each independently represent an alkyl group, R²¹⁴ and R²¹⁵ may be bonded to each other to form a ring, and in a case where R²¹³ and R²¹⁵ each independently represent an alkyl group, R²¹³ and R²¹⁵ may be bonded to each other to form a ring.

In Formula (BZ1-1), R²¹¹ and R²¹² each independently represent a halogen atom or an alkyl group. Examples of the halogen atom include a fluorine atom, a chlorine atom, a bromine atom, and an iodine atom, and a halogen atom is preferable. The number of carbon atoms in the alkyl group is preferably 1 to 10 and more preferably 1 to 6. Examples of the alkyl group include a linear alkyl group, a branched alkyl group, and a cyclic alkyl group, and a linear alkyl group or a branched alkyl group is preferable and a linear alkyl group is more preferable. The alkyl group may have a substituent or may be unsubstituted. The alkyl group is preferably an alkyl group having a halogen atom as a substituent, and more preferably an alkyl group (fluoroalkyl group) having a fluorine atom as a substituent. In addition, the fluoroalkyl group is preferably a perfluoroalkyl group. In Formula (BZ1-1), in a case where R²¹¹ and R²¹² each independently represent an alkyl group, R²¹¹ and R²¹² may be bonded to each other to form a ring.

In Formula (BZ2-1), R²¹³ to R²¹⁵ each independently represent a halogen atom or an alkyl group. The halogen atom and the alkyl group are the same as those described in Formula (BZ1-1), and the preferred range is also the same. In Formula (BZ2-1), in a case where R²¹³ and R²¹⁴ each independently represent an alkyl group, R²¹³ and R²¹⁴ may be bonded to each other to form a ring. In addition, in a case where R²¹⁴ and R²¹⁵ each independently represent an alkyl group, R²¹⁴ and R²¹⁵ may be bonded to each other to form a ring. In addition, in a case where R²¹³ and R²¹⁵ each independently represent an alkyl group, R²¹³ and R²¹⁵ may be bonded to each other to form a ring.

From the reason that the anion is highly stable and easily ionized, the anion of the compound D is preferably an anion represented by Formula (1) or Formula (2) and more preferably an anion represented by Formula (1).

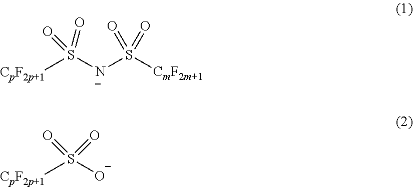

In the formulae, n, m, and p each independently represent an integer of 1 or more.

n and m in Formula (1) are each independently preferably 1 to 10 and more preferably 1 to 6.

p in Formula (2) is preferably 1 to 10 and more preferably 1 to 6.

Specific examples of the anion of the compound D include anions having structures shown below.

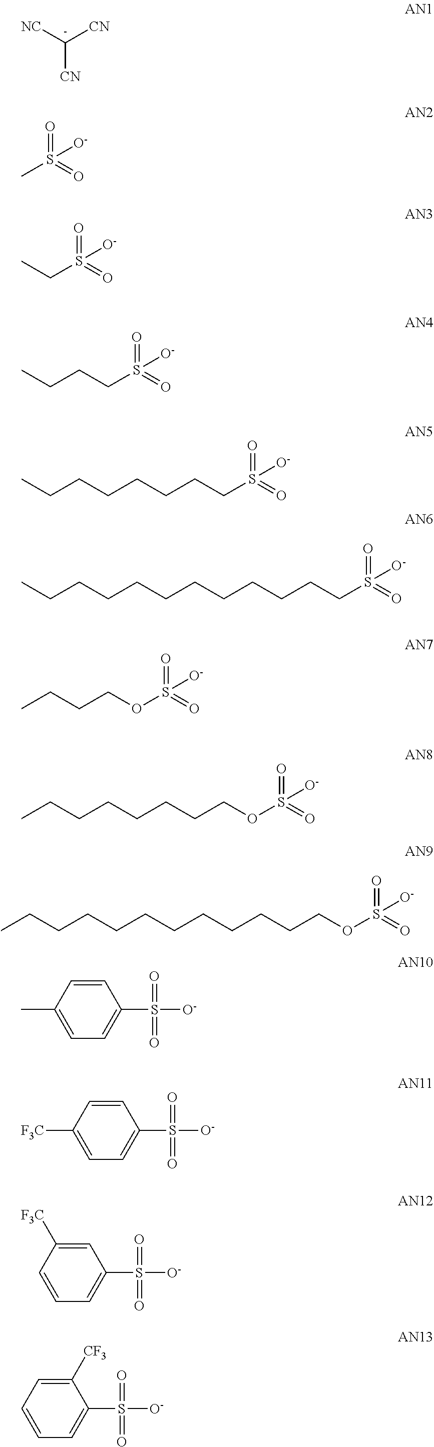

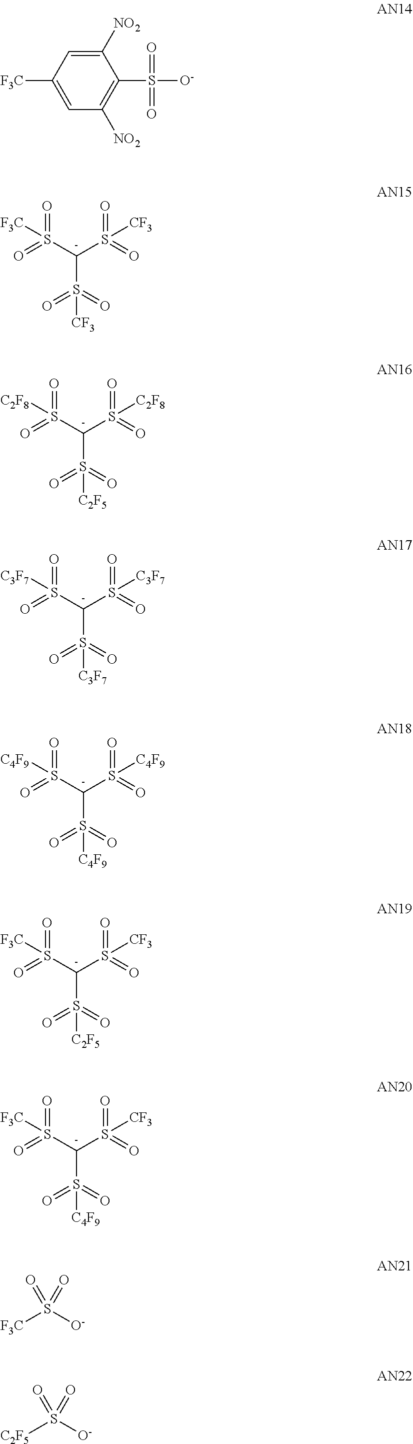

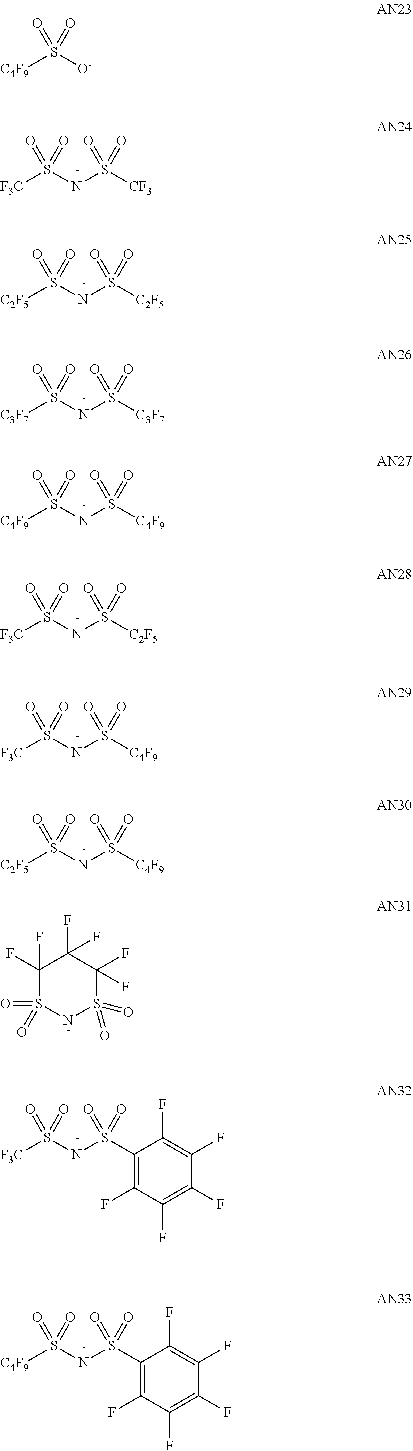

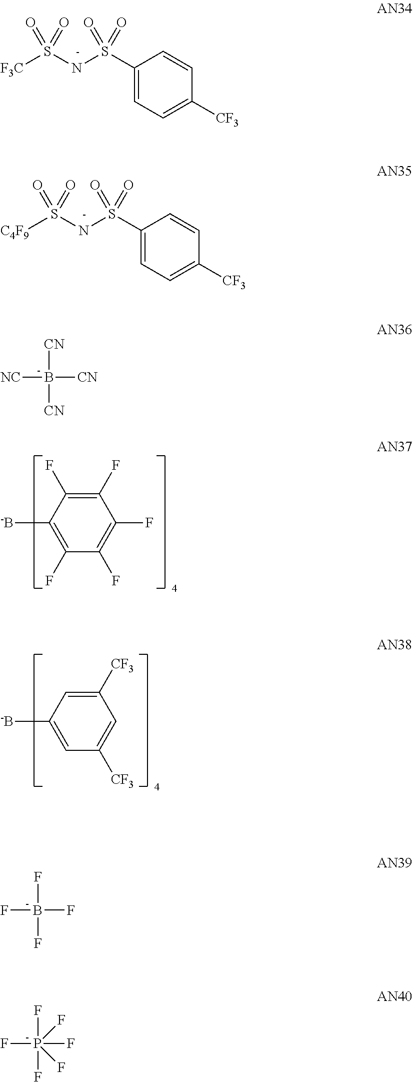

In addition, specific examples thereof also include (CF₃)₃PF₃⁻, (C₂F₅)₂PF₄⁻, (C₂F₅)₃PF₃⁻, [(CF₃)₂CF]₂PF₄⁻, [(CF₃)₂CF]₃PF₃⁻, (n-C₃F₇)₂PF₄⁻, (n-C₃F₇)₃PF₃⁻, (n-C₄F₉)₃PF₃⁻, (C₂F₅)(CF₃)₂PF₃⁻, [(CF₃)₂CFCF₂]₂PF₄⁻, [(CF₃)₂CFCF₂]₃PF₃⁻, (n-C₄F₉)₂PF₄⁻, (n-C₄F₉)₃PF₃⁻, (C₂F₄H)(CF₃)₂PF₃⁻, (C₂F₃H₂)₃PF₃⁻, (C₂F₅)(CF₃)₂PF₃⁻, (CF₃)₄B⁻, (CF₃)₃BF⁻, (CF₃)₂BF₂⁻, (CF₃)BF₃⁻, (C₂F₅)₄B⁻, (C₂F₅)₃BF⁻, (C₂F₅)BF₃⁻, (C₂F₅)₂BF₂⁻, (CF₃)(C₂F₅)₂BF⁻, (CF₃C₆H₄)₄B⁻, (C₆F₅)₂BF₂⁻, (C₆F₅)BF₃⁻, (C₆H₃F₂)₄B⁻, B(CN)F₃⁻, B(CN)₂F₂⁻, B(CN)₃F⁻, (CF₃)₃B(CN)⁻, (CF₃)₂B(CN)₂⁻, (C₂F₅)₃B(CN)⁻, (C₂F₅)₂B(CN)₂⁻, (n-C₃F₇)₃B(CN)⁻, (n-C₄F₉)₃B(CN)⁻, (n-C₄F₉)₂B(CN)₂⁻, (n-C₆F₁₃)₃B(CN)⁻, (CHF₂)₃B(CN)⁻, (CHF₂)₂B(CN)₂⁻, (CH₂CF₃)₃B(CN)⁻, (CH₂CF₃)₂B(CN)₂⁻, (CH₂C₂F₅)₃B(CN)⁻, (CH₂C₂F₅)₂B(CN)₂⁻, (CH₂CH₂C₃F₇)₂B(CN)₂⁻, (n-C₃F₇CH₂)₂B(CN)₂⁻, (C₆H₅)B(CN)⁻, and anions having the following structures.

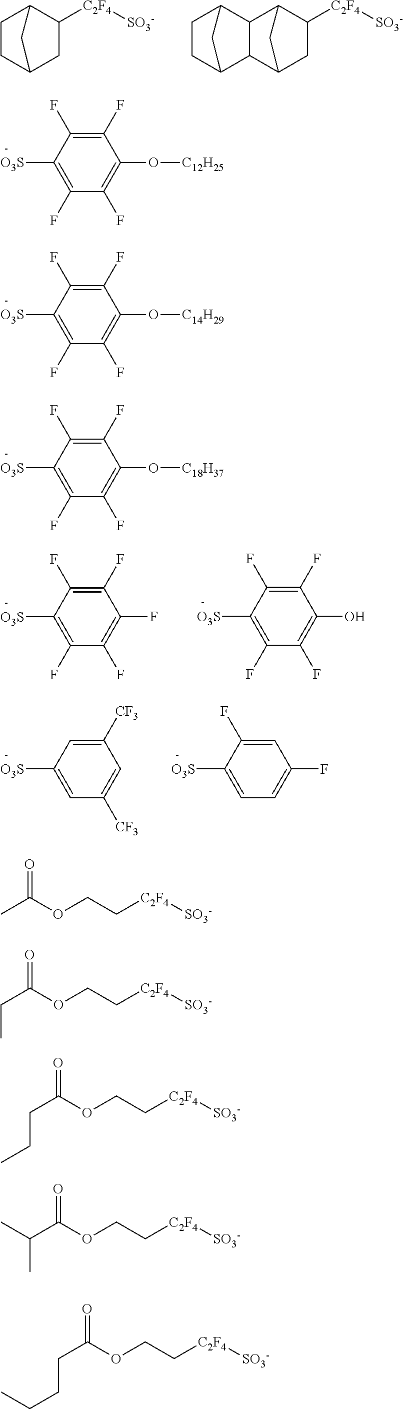

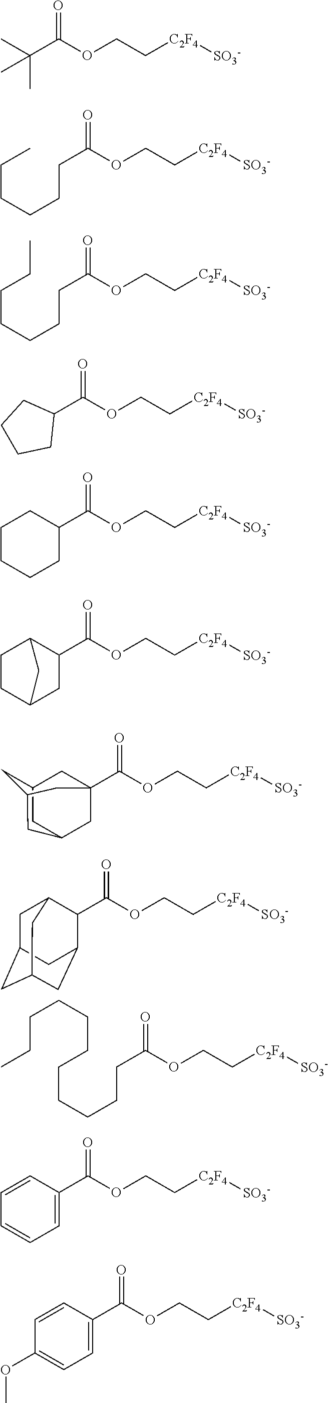

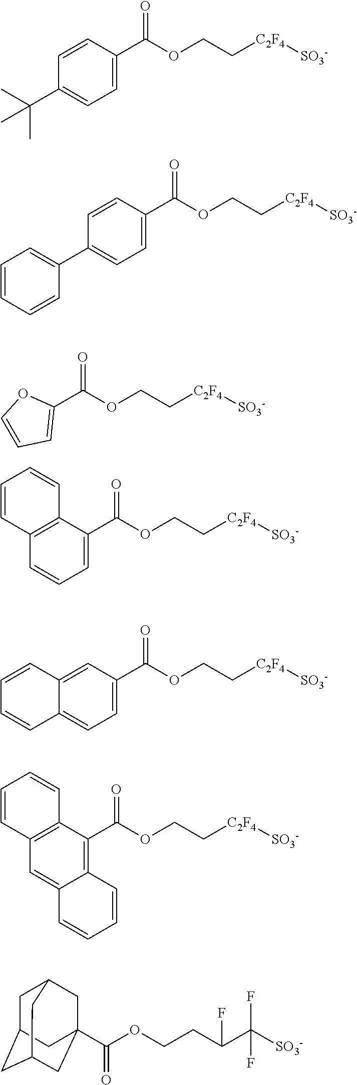

A content of the compound D in the total solid content of the photosensitive composition is preferably 0.1 to 15 mass %. The upper limit is preferably 12 mass % or less, more preferably 10 mass % or less, still more preferably 8 mass % or less, and particularly preferably 5 mass % or less. The lower limit is preferably 0.5 mass % or more and more preferably 1 mass % or more. The content of the compound D in the total solid content of the photosensitive composition is particularly preferably 1 to 5 mass %.

A content of the compound D is preferably 0.01 to 4.00 mol, more preferably 0.05 to 3.00 mol, and still more preferably 0.10 to 2.00 mol with respect to 1 mol of the colorant A. In a case where the molar ratio of the compound D to the colorant A is within the above-described range, it is possible to form a pixel in which chipping is further suppressed. In addition, the content of the compound D is preferably 0.1 to 20 parts by mass, more preferably 1 to 10 parts by mass, and still more preferably 2 to 8 parts by mass with respect to 100 parts by mass of the colorant A. In a case where the mass ratio of the compound D to the colorant A is within the above-described range, it is possible to form a pixel in which chipping is further suppressed.

The content of the compound D is preferably 0.6 to 60 parts by mass, more preferably 6 to 43 parts by mass, and still more preferably 10 to 30 parts by mass with respect to 100 parts by mass of the polymerizable compound C. In a case where the mass ratio of the compound D to the polymerizable compound C is within the above-described range, it is possible to form a pixel in which chipping is further suppressed.

<<Resin>>

The photosensitive composition according to the embodiment of the present invention preferably contains a resin. The resin is blended in, for example, an application for dispersing particles such as a pigment in the photosensitive composition or an application as a binder. Mainly, a resin which is used for dispersing particles such as a pigment is also referred to as a dispersant. However, such applications of the resin are only exemplary, and the resin can also be used for other purposes in addition to such applications.

The weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

The photosensitive composition according to the embodiment of the present invention preferably includes a resin having an acid group. The resin having an acid group can be used as an alkali-soluble resin. With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group. In addition, a method of introducing the acid group into the resin is not particularly limited, and examples thereof include the method described in JP6349629B. Further, examples of the method of introducing the acid group into the resin include a method of introducing an acid group by reacting an acid anhydride with a hydroxy group generated by a ring-opening reaction of an epoxy group.

Examples of the acid group included in the resin having an acid group include a carboxyl group, a phosphoric acid group, a sulfo group, and a phenolic hydroxy group, and a carboxyl group is preferable.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. A weight-average molecular weight (Mw) of the resin having an acid group is preferably 5000 to 100000. In addition, the number-average molecular weight (Mn) of the resin having an acid group is preferably 1000 to 20000.

The photosensitive composition according to the embodiment of the present invention preferably includes a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the basic group included in the resin having a basic group include a group represented by Formula (a-1) and a group represented by Formula (a-2).

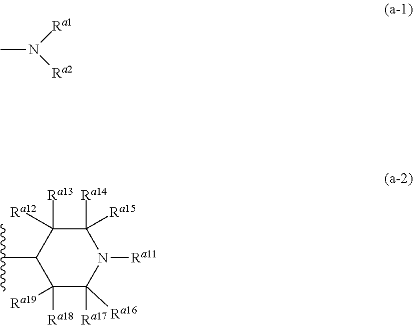

In Formula (a-1), R^{a1} and R^{a2} each independently represent a hydrogen atom, an alkyl group, or an aryl group, and R^{a1} and R^{a2} may be bonded to each other to form a ring;

in Formula (a-2), R^{a11} represents a hydrogen atom, a hydroxy group, an alkyl group, an alkoxy group, an aryl group, an aryloxy group, an acyl group, or an oxyradical, and R^{a12} to R^{a19} each independently represent a hydrogen atom, an alkyl group, or an aryl group.

The alkyl group represented by R^{a1}, R^{a2}, R^{a11} to R^{a19} preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear. The alkyl group may have a substituent.

The aryl group represented by R^{a1}, R^{a2}, R^{a11} to R^{a19} preferably has 6 to 30 carbon atoms, more preferably has 6 to 20 carbon atoms, and still more preferably has 6 to 12 carbon atoms. The aryl group may have a substituent.

The alkoxy group represented by R^{a11} preferably has 1 to 30 carbon atoms, more preferably has 1 to 15 carbon atoms, still more preferably has 1 to 8 carbon atoms, and particularly preferably has 1 to 5 carbon atoms. The alkoxy group may have a substituent.

The aryloxy group represented by R^{a11} preferably has 6 to 30 carbon atoms, more preferably has 6 to 20 carbon atoms, and still more preferably has 6 to 12 carbon atoms. The aryloxy group may have a substituent.

The acyl group represented by R^{a11} preferably has 2 to 30 carbon atoms, more preferably has 2 to 20 carbon atoms, and still more preferably has 2 to 12 carbon atoms. The acyl group may have a substituent.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK Chemie Japan), SOLSPERSE 11200, 13240, 13650, 13940, 24000, 26000, 28000, 3200, 32500, 32550, 32600, 33000, 34750, 35100, 35200, 37500, 38500, 3900, 53095, 56000, and 7100 (all of which are manufactured by Lubrizol Japan Ltd.), and Efka PX 4300, 4330, 4046, 4060, and 4080 (all of which are manufactured by BASF). In addition, as the resin having a basic group, a block copolymer (B) described in paragraph Nos. 0063 to 0112 of JP2014-219665A or a block copolymer A1 described in paragraph Nos. 0046 to 0076 of JP2018-156021A, the contents of which are incorporated herein by reference.

It is also preferable that the photosensitive composition according to the embodiment of the present invention includes the resin having an acid group and the resin having a basic group, respectively. According to this aspect, the storage stability of the photosensitive composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

As the resin, it is also preferable to use a resin including a repeating unit derived from a compound represented by Formula (ED1) and/or a compound represented by Formula (ED2) (hereinafter, these compounds will also be referred to as an “ether dimer”).

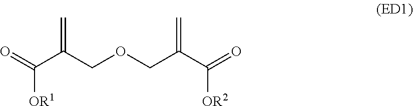

In Formula (ED1), R¹ and R² each independently represent a hydrogen atom or a hydrocarbon group having 1 to 25 carbon atoms, which may have a substituent.

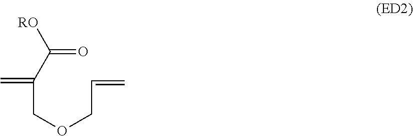

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

As the resin, it is also preferable to use a resin including a repeating unit having a polymerizable group.

As the resin, it is also preferable to use a resin including a repeating unit derived from a compound represented by Formula (X).

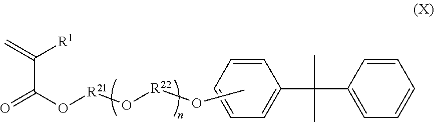

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to use a resin (hereinafter, also referred to as a resin Ac) having an aromatic carboxyl group. The resin Ac may include the aromatic carboxyl group in the main chain of the repeating unit, or in the side chain of the repeating unit. It is preferable that the aromatic carboxyl group is included in the main chain of the repeating unit.

In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) or a repeating unit represented by Formula (Ac-2). The resin including the repeating unit represented by Formula (Ac-2) is a graft resin.

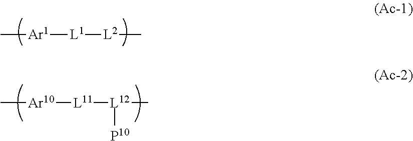

In Formula (Ac-1), Ar¹ represents a group including an aromatic carboxyl group, L¹ represents —COO— or —CONH—, and L² represents a divalent linking group.

In Formula (Ac-2), Ar¹⁰ represents a group including an aromatic carboxyl group, L¹¹ represents —COO— or —CONH—, L¹² represents a trivalent linking group, and P¹⁰ represents a polymer chain.

In Formula (Ac-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

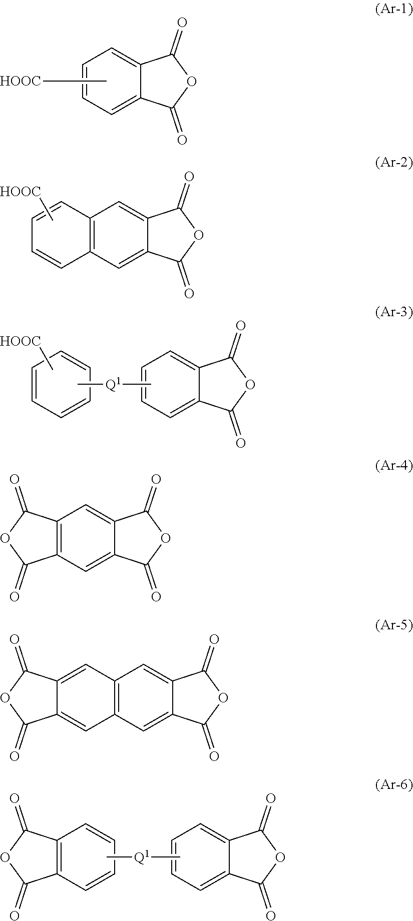

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

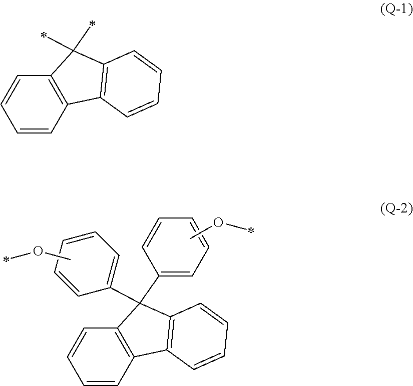

The group including an aromatic carboxyl group, which is represented by Ar¹, may have a polymerizable group. Examples of the polymerizable group include an ethylenically unsaturated bond-containing group and a cyclic ether group, and an ethylenically unsaturated bond-containing group is preferable. Specific examples of the group including an aromatic carboxyl group represented by Ar¹ include a group represented by Formula (Ar-11), a group represented by Formula (Ar-12), and a group represented by Formula (Ar-13).

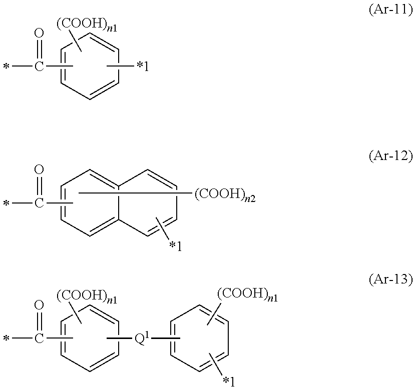

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formulae (Ar-11) to (Ar-13), * I represents a bonding position with L¹.

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by -L^{2a}-O—. Examples of L^{2a} include an alkylene group; an arylene group; a group formed by a combination of an alkylene group and an arylene group; and a group formed by a combination of at least one selected from an alkylene group or an arylene group, and at least one selected from —O—, —CO—, —COO—, —OCO—, —NH—, or —S—, and an alkylene group is preferable. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxyl group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

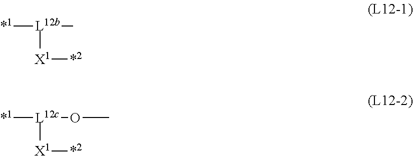

In Formula (L12-1), L^{12b} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L12-2), L^{12c} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxyl group is a resin having the repeating unit represented by Formula (Ac-2), this resin is preferably used as a dispersant.

The polymer chain represented by P¹⁰ may include a polymerizable group. Examples of the polymerizable group include an ethylenically unsaturated bond-containing group and a cyclic ether group, and an ethylenically unsaturated bond-containing group is preferable.

In Formula (Ac-2), the polymer chain represented by P¹⁰ is preferably a polymer chain including a repeating unit represented by Formulae (P-1) to (P-5), and more preferably a polymer chain including a repeating unit represented by (P-5).

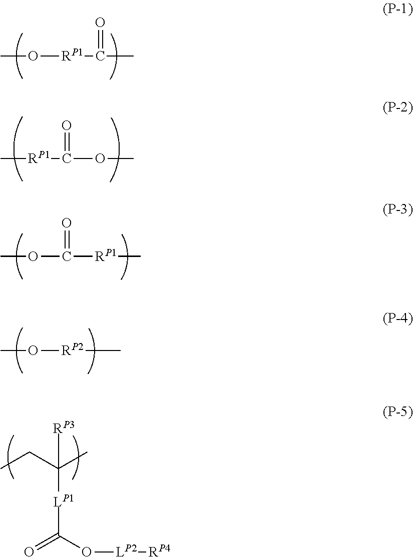

In the formulae, R^{P1} and R^{P2} each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{P3} represents a hydrogen atom or a methyl group.

In the formulae, L^{P1} represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxyl group, an alkyl group, an aryl group, a heteroaryl group, an alkoxy group, an aryloxy group, a heteroaryloxy group, an alkylthioether group, an arylthioether group, a heteroarylthioether group, a (meth)acryloyl group, an oxetanyl group, and a blocked isocyanate group. The blocked isocyanate group in the present specification is a group capable of generating an isocyanate group by heat, and preferred examples thereof include a group in which an isocyanate group is protected by reacting a blocking agent and an isocyanate group. Examples of the blocking agent include oxime compounds, lactam compounds, phenol compounds, alcohol compounds, amine compounds, active methylene compounds, pyrazole compounds, mercaptan compounds, imidazole compounds, and imide compounds. Examples of the blocking agent include compounds described in paragraphs 0115 to 0117 of JP2017-067930A, the contents of which are incorporated herein by reference. In addition, the blocked isocyanate group is preferably a group capable of generating an isocyanate group by heat of 90° C. to 260° C.

It is preferable that the polymer chain represented by P¹⁰ has at least one group (hereinafter, also referred to as a “functional group A”) selected from the group consisting of a (meth)acryloyl group, an oxetanyl group, a blocked isocyanate group, and a t-butyl group. The functional group A is more preferably at least one selected from the group consisting of a (meth)acryloyl group, an oxetanyl group, and a blocked isocyanate group. In a case where the polymer chain includes the functional group A, it is easy to form a film having excellent solvent resistance. In particular, the effects described above are remarkable in a case of including at least one group selected from a (meth)acryloyl group, an oxetanyl group, and a blocked isocyanate group.

In addition, it is more preferable that the polymer chain represented by P¹⁰ is a polymer chain having a repeating unit including the above-described functional group A in the side chain. In addition, a proportion of the repeating unit including the above-described functional group A in the side chain with respect to all repeating units constituting P¹⁰ is preferably 5 mass % or more, more preferably 10 mass % or more, and still more preferably 20 mass % or more. The upper limit may be 100 mass %, and is preferably 90 mass % or less and more preferably 60 mass % or less.

In addition, it is also preferable that the polymer chain represented by P¹⁰ has a repeating unit including an acid group. Examples of the acid group include a carboxyl group, a phosphoric acid group, a sulfo group, and a phenolic hydroxy group. A proportion of the repeating unit including an acid group in all repeating units constituting P¹⁰ is preferably 1 to 30 mass %, more preferably 2 mass % to 20 mass %, and still more preferably 3 to 10 mass %.

The resin preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. In addition, the basic dispersant (basic resin) represents a resin in which the amount of the basic group is larger than the amount of the acid group.

The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. The acid value of the acidic dispersant (acidic resin) is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more.

The basic dispersant (basic resin) is preferably a resin in which the amount of the basic group is 60 mol % or more in a case where the total amount of the acid group and the basic group is 100 mol %. The basic group included in the basic dispersant is preferably an amino group. An amine value of the basic dispersant (basic resin) is preferably 5 to 100 mgKOH/g. The upper limit is preferably 80 mgKOH/g or less, more preferably 60 mgKOH/g or less, and still more preferably 45 mgKOH/g or less. The lower limit is preferably 10 mgKOH/g or more, more preferably 15 mgKOH/g or more, and still more preferably 20 mgKOH/g or more.

It is also preferable that the resin used as a dispersant is a graft resin. With regard to details of the graft resin, reference can be made to the description in paragraph Nos. 0025 to 0094 of JP2012-255128A, the contents of which are incorporated herein by reference. In addition, as the graft resin, it is also preferable to use a resin including a repeating unit represented by Formula (Ac-2) described above.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0022 to 0097 of JP2009-203462A and paragraph Nos. 0102 to 0166 of JP2012-255128A, and the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. The content of the repeating unit having an ethylenically unsaturated bond-containing group in the side chain is preferably 10 mol % or more, more preferably 10 to 80 mol %, and still more preferably 20 to 70 mol % with respect to all repeating units of the resin. In addition, as the dispersant, a resin described in JP20184087939A can also be used.

A commercially available product is also available as the dispersant, and specific examples thereof include DISPERBYK series manufactured by BYK Chemie Japan, Solsperse series manufactured by Lubrizol Japan Ltd., Efka series manufactured by BASF, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the resin used as a dispersant, block copolymers (EB-1) to (EB-9) described in paragraph Nos. 0219 to 0221 of JP6432077B can also be used.

The content of the resin in the total solid content of the photosensitive composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less. In addition, the content of the resin (alkali-soluble resin) having an acid group in the total solid content of the photosensitive composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less. In addition, from the reason that excellent developability is easily obtained, the content of the resin (alkali-soluble resin) having an acid group in the total amount of the resin is preferably 30 mass % or more, more preferably 50 mass % or more, still more preferably 70 mass % or more, and particularly preferably 80 mass % or more. The upper limit may be 100 mass %, 95 mass %, or 90 mass % or less. The photosensitive composition according to the embodiment of the present invention may include one kind of resin or two or more kinds of resins. In a case of including two or more kinds of resins, the total amount thereof is preferably within the above-described range.

<<Compound Having Cyclic Ether Group>>

The photosensitive composition according to the embodiment of the present invention preferably contains a compound having a cyclic ether group. The compound having a cyclic ether group can be used, for example, as a thermosetting agent. In a case where the photosensitive composition contains a compound having a cyclic ether group, a stronger film can be formed and the occurrence of chipping during development can be more effectively suppressed. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The compound having a cyclic ether group may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the compound having a cyclic ether group is preferably 200 to 100000 and more preferably 500 to 50000. The upper limit of the weight-average molecular weight is preferably 10000 or less, more preferably 5000 or less, and still more preferably 3000 or less.

As the compound having a cyclic ether group, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

In addition, as the compound having a cyclic ether group, the resin having a cyclic ether group among the resins described in the above section can also be used.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

A content of the compound having a cyclic ether group in the total solid content of the photosensitive composition is preferably 0.1 to 20 mass %. The lower limit is preferably 0.5 mass % or more and more preferably 1 mass % or more. The upper limit is more preferably 15 mass % or less and still more preferably 10 mass % or less. The photosensitive composition according to the embodiment of the present invention may include one kind of compound having a cyclic ether group or two or more kinds thereof. In a case of including two or more kinds of compounds having a cyclic ether group, the total amount thereof is preferably within the above-described range.

<<Pigment Derivative>>

The photosensitive composition according to the embodiment of the present invention can contain a pigment derivative. In a case where the photosensitive composition according to the embodiment of the present invention includes the pigment, it is preferable that the photosensitive composition according to the embodiment of the present invention includes a pigment derivative. Examples of the pigment derivative include a compound having a structure in which a part of a chromophore is substituted with an acid group or a basic group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of the molar absorption coefficient of the transparent pigment derivative in a wavelength region of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·ol⁻¹·cm⁻¹ or more.

Specific examples of the pigment derivative include compounds described in JP1981-118462A (JP-S56-118462A), JP988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/0248% A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A. JP2014-199308A. JP2014-085562A. JP2014-035351A, JP2008-081565A, and JP2019-109512A.

In a case where the photosensitive composition according to the embodiment of the present invention contains a pigment derivative, the content of the pigment derivative in the total solid content of the photosensitive composition is preferably 0.3 to 20 mass %. The lower limit is preferably 0.6 mass % or more and more preferably 0.9 mass % or more. The upper limit is preferably 15 mass % or less, more preferably 12.5 mass % or less, and still more preferably 10 mass % or less. In addition, the content of the pigment derivative is preferably 1 to 30 parts by mass with respect to 100 parts by mass of the pigment. The lower limit is preferably 2 parts by mass or more and more preferably 3 parts by mass or more. The upper limit is preferably 25 parts by mass or less, more preferably 20 parts by mass or less, and still more preferably 15 parts by mass less. In the photosensitive composition according to the embodiment of the present invention, the pigment derivative may be used singly or in combination of two or more kinds thereof. In a case where two or more kinds thereof are used in combination, the total amount thereof is preferably within the above-described range.

<<Silane Coupling Agent>>

The photosensitive composition according to the embodiment of the present invention can contain a silane coupling agent. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

In a case where the photosensitive composition according to the embodiment of the present invention contains a silane coupling agent, the content of the silane coupling agent in the total solid content of the photosensitive composition is preferably 0.1 to 5 mass %. The upper limit is preferably 3 mass % or less and more preferably 2 mass % or less. The lower limit is preferably 0.5 mass % or more and more preferably 1 mass % or more. In the photosensitive composition according to the embodiment of the present invention, the silane coupling agent may be used singly or in combination of two or more kinds thereof. In a case where two or more kinds thereof are used, the total amount thereof is preferably within the above-described range.

<<Solvent>>

The photosensitive composition according to the embodiment of the present invention preferably contains a solvent. The solvent is preferably an organic solvent. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, and 3-methoxybutanol. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 parts per billion (ppb) by mass or less. Optionally, an organic solvent having a metal content at a level of parts per trillion (ppt) by mass may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

A content of the organic solvent in the photosensitive composition is preferably 10 to 95 mass %, more preferably 20 to 90 mass %, and still more preferably 30 to 90 mass %.

In addition, from the viewpoint of environmental regulation, it is preferable that the photosensitive composition according to the embodiment of the present invention does not substantially contain environmentally regulated substances. In the present invention, the description “does not substantially contain environmentally regulated substances” means that the content of the environmentally regulated substances in the photosensitive composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the photosensitive composition according to the embodiment of the present invention, and may be incorporated into the photosensitive composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is equal to or higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, photosensitive composition produced by mixing these compounds, or the like.

<<Polymerization Inhibitor>>

The photosensitive composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the photosensitive composition is preferably 0.0001 to 5 mass %.

<<Surfactant>>

The photosensitive composition according to the embodiment of the present invention can contain a surfactant. As the surfactant, various surfactants such as a fluorine-based surfactant, a nonionic surfactant, a cationic surfactant, an anionic surfactant, and a silicon-based surfactant can be used. Examples of the surfactant include surfactants described in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the photosensitive composition, liquid characteristics (particularly, fluidity) are further improved, and liquid saving property can be further improved. In addition, it is possible to form a film with a small thickness unevenness.

The fluorine content in the fluorine-based surfactant is suitably 3 to 40 mass %, and more preferably 5 to 30 mass % and particularly preferably 7% to 25 mass %. The fluorine-based surfactant in which the fluorine content is within the above-described range is effective in terms of the evenness of the thickness of the coating film or liquid saving property and the solubility of the surfactant in the photosensitive composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, surfactants described in paragraph Nos. 0117 to 0132 of JP2011-132503A, and surfactants described in JP2020-008634A, the contents of which are incorporated herein by reference. Examples of a commercially available product of the fluorine-based surfactant include. MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90. R-94. RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 710FM, 610FM, 601AD, 601ADH2, 602A, 215M, and 245F (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

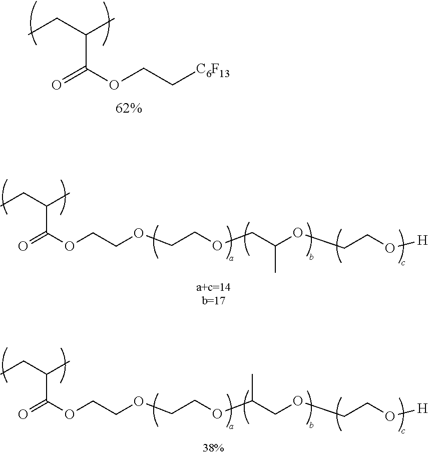

The weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF). SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

A content of the surfactant in the total solid content of the photosensitive composition is preferably 0.001 mass % to 5.0 mass % and more preferably 0.005 to 3.0 mass %. In the photosensitive composition according to the embodiment of the present invention, the surfactant may be used singly or in combination of two or more kinds thereof. In a case where two or more kinds thereof are used, the total amount thereof is preferably within the above-described range.

<<Ultraviolet Absorber>>

The photosensitive composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of details thereof include compounds described in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the photosensitive composition is preferably 0.01 to 10 mass % and more preferably 0.01 to 5 mass %. In the photosensitive composition according to the embodiment of the present invention, the ultraviolet absorber may be used singly or in combination of two or more kinds thereof. In a case where two or more kinds thereof are used, the total amount thereof is preferably within the above-described range.

<<Antioxidant>>

The photosensitive composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraph Nos. 0023 to 0048 of JP6268967B can also be used. A content of the antioxidant in the total solid content of the photosensitive composition is preferably 0.01 to 20 mass % and more preferably 0.3 to 15 mass %. In the photosensitive composition according to the embodiment of the present invention, the antioxidant may be used singly or in combination of two or more kinds thereof. In a case where two or more kinds thereof are used, the total amount thereof is preferably within the above-described range.

<<Other Components>>

Optionally, the photosensitive composition according to the embodiment of the present invention may further contain a sensitizer, a curing accelerator, a filler, a thermal curing accelerator, a plasticizer, and other auxiliary agents (for example, conductive particles, a filling agent, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, as desired, the photosensitive composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the photosensitive composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure. In addition, in this case, the core portion may be hollow.

The photosensitive composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the photosensitive composition according to the embodiment of the present invention, the content of liberated metal which is not bonded to or coordinated with a pigment or the like is preferably 100 ppm or less, more preferably 50 ppm or less, and still more preferably 10 ppm or less, it is particularly preferable to not contain the liberated metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the photosensitive composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the photosensitive composition include washing with ion exchange water, filtration, ultrafiltration, and purification with an ion exchange resin.

It is also preferable that the photosensitive composition according to the embodiment of the present invention does not substantially include terephthalic acid ester. Here, the “does not substantially include” means that the content of terephthalic acid ester is 1000 ppb by mass or less in the total amount of the photosensitive composition, and it is more preferable to be 100 ppb by mass or less and particularly preferable to be 0.

From the viewpoint of environmental regulation, the use of perfluoroalkyl sulfonic acid and a salt thereof and use of perfluoroalkyl carboxylic acid and a salt thereof may be restricted. In the photosensitive composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1000 ppb, more preferably in a range of 0.05 ppb to 500 ppb, and still more preferably in a range of 0.1 ppb to 300 ppb with respect to the total solid content of the photosensitive composition. The photosensitive composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a photosensitive composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The photosensitive composition according to the embodiment of the present invention may include the perfluoroalkyl sulfonic acid and a salt thereof and the perfluoroalkyl carboxylic acid and a salt thereof within the maximum allowable range.

The moisture content in the photosensitive composition according to the embodiment of the present invention is usually 3 mass % or less, preferably 0.01 to 1.5 mass % and more preferably in a range of 0.1 to 1.0 mass %. The moisture content can be measured by a Karl Fischer method.

The photosensitive composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 23° C. As for a method for measuring the viscosity, the viscosity can be measured, for example, with a temperature being adjusted to 23° C., using a viscometer RE85L (rotor: 1°34′×R24, measurement range of 0.6 to 1,200 mPa·s) manufactured by Toki Sangyo Co., Ltd.

In a case where the photosensitive composition according to the embodiment of the present invention is used as a color filter in applications for a liquid crystal display device, the voltage holding ratio of a liquid crystal display element comprising a color filter is preferably 70% or more, and more preferably 90% or more. A known method for obtaining a high voltage holding ratio can be appropriately incorporated, and examples of typical methods include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Storage Container>

A storage container of the photosensitive composition according to the embodiment of the present invention is not particularly limited, and a known storage container can be used. In addition, as the storage container, it is also preferable to use a multilayer bottle having a container interior wall constituted with six layers from six kinds of resins or a bottle having a 7-layer structure from 6 kinds of resins for the purpose of suppressing infiltration of impurities into raw materials or photosensitive compositions. Examples of such a container include the containers described in JP2015-123351A. In addition, for the purpose of preventing metal elution from the container interior wall, improving storage stability of the photosensitive composition, and suppressing the alteration of components, it is also preferable that the interior wall of the photosensitive composition is formed of glass, stainless steel, or the like.

<Method for Preparing Photosensitive Composition>

The photosensitive composition according to the embodiment of the present invention can be prepared by mixing the above-described components with each other. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

In addition, in the preparation of the photosensitive composition, a process of dispersing the pigment is also preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described photosensitive composition according to the embodiment of the present invention. The film according to the embodiment of the present invention can be used for a color filter or the like. Specifically, the film according to the embodiment of the present invention can be preferably used as a colored layer (pixel) of a color filter. Examples of the colored pixel include a red pixel, a blue pixel, a green pixel, a yellow pixel, a cyan pixel, and a magenta pixel. The thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

<Color Filter>

Next, the color filter according to an embodiment of the present invention will be described. The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the film according to the embodiment of the present invention can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

A width of the pixel included in the color filter is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 500 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured, for example, using an ultra-high resistance meter 5410 (manufactured by Advantest Corporation).

In the color filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1 to 70 mass % and still more preferably 1 to 60 mass % with respect to the total mass of the protective layer.

In addition, as the protective layer, the protective layers described in paragraph Nos. 0073 to 0092 of JP2017-151176A can also be used.

The color filter may have a base layer. The base layer can also be formed using, for example, a composition obtained by removing a colorant from the above-described photosensitive composition according to the embodiment of the present invention. The surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the resin composition is good. The surface contact angle of the base layer can be adjusted by, for example, a method of adding a surfactant.

In addition, in the green pixel of the color filter, C. I. Pigment Green 7, C. I. Pigment Green 36, C. I. Pigment Yellow 139, and C. I. Pigment Yellow 185 may be combined to form green, or C. I. Pigment Green 58, C. I. Pigment Yellow 150, and C. I. Pigment Yellow 185 may be combined to form green.

<Method for Manufacturing Color Filter>

Next, a method for manufacturing a color filter using the photosensitive composition according to the embodiment of the present invention will be described. The method for manufacturing a color filter preferably includes a step of forming a photosensitive composition layer on a support using the above-described photosensitive composition according to the embodiment of the present invention, a step of exposing the photosensitive composition layer in a patterned manner, and a step of removing a non-exposed portion of the photosensitive composition layer by development to form a pattern (pixel). A step (pre-baking step) of baking the photosensitive composition layer and a step (post-baking step) of baking the developed pattern (pixel) may be provided, optionally.

In the step of forming a photosensitive composition layer, the photosensitive composition layer is formed on a support using the photosensitive composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate for improving adhesiveness to an upper layer, preventing the diffusion of materials, or planarizing the surface of the substrate. The base layer may be formed of a composition obtained by removing a colorant from the photosensitive composition described in the present specification, a composition including the resin, polymerizable compound, surfactant, and the like described in the present specification, or the like.

As a method for applying the photosensitive composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the photosensitive composition, reference can be made to the description in WO2017/030174A and WO2017/018419A, the contents of which are incorporated herein by reference.

The photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive composition layer is exposed in a patterned manner (exposing step). For example, the photosensitive composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, or substantially oxygen-free) or in a high-oxygen atmosphere having an oxygen concentration of more than 21% by volume (for example, 22% by volume, 30% by volume, or 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the photosensitive composition layer is removed by development to form a pattern (pixel). The non-exposed portion of the photosensitive composition layer can be removed by development using a developer. Thus, the photosensitive composition layer of the non-exposed portion in the exposing step is eluted into the developer, and as a result, only a photocured portion remains. As the developer, an organic alkaline developer causing no damage on a base of element, circuit, or the like is desirable. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an aqueous alkaline solution (alkali developer) in which an alkali agent is diluted with pure water is preferable. Examples of the alkali agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001 to 10 mass % and more preferably 0.01 to 1 mass %. In addition, the developer may further contain a surfactant. Examples of the surfactant include the surfactants described above, and the surfactant is preferably a nonionic surfactant. From the viewpoint of convenience of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive composition layer after development while rotating the support on which the photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

<Solid-State Imaging Element>

The solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film, and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. In this case, it is preferable that the partition wall has a lower refractive index than each colored pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

The image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Preparation of Pigment Dispersion Liquid>

Raw materials described in the following table were mixed, and then 230 parts by mass of zirconia beads having a diameter of 0.3 mm were added thereto to perform a dispersion treatment for 5 hours using a paint shaker. The beads were separated by filtration, and a dispersion liquid was produced.

TABLE 1

| | | | | | | | Concentration of | Concentration of |
|---|---|---|---|---|---|---|---|---|
| | Pigment | | Dispersant | | Solvent | | solid contents of | pigment in |
| | | Part by | | Part by | | Part by | dispersion liquid | dispersion liquid |
| | Type | mass | Type | mass | Type | mass | (mass %) | (mass %) |
| Dispersion | Pg-1 | 19.4 | Dp-1 | 2.95 | S-1 | 165.3 | 13.27 | 10.18 |
| liquid 1 | | | Dp-2 | 2.95 | | | | |
| Dispersion | Pg-2 | 19.4 | Dp-1 | 2.95 | S-1 | 165.3 | 13.27 | 10.18 |
| liquid 2 | | | Dp-2 | 2.95 | | | | |
| Dispersion | Pg-3 | 19.4 | Dp-1 | 2.95 | S-1 | 165.3 | 13.27 | 10.18 |
| liquid 3 | | | Dp-2 | 2.95 | | | | |
| Dispersion | Pg-4 | 19.4 | Dp-1 | 2.95 | S-1 | 165.3 | 13.27 | 10.18 |
| liquid 4 | | | Dp-2 | 2.95 | | | | |
| Dispersion | Pg-5 | 19.4 | Dp-1 | 2.95 | S-1 | 165.3 | 13.27 | 10.18 |
| liquid 5 | | | Dp-2 | 2.95 | | | | |
| Dispersion | Pg-1 | 19.4 | Dp-3 | 19.67 | S-1 | 151.53 | 13.27 | 10.18 |
| liquid 6 | | | | | | | | |
| Dispersion | Pg-1 | 19.4 | Dp-4 | 19.67 | S-1 | 151.53 | 13.27 | 10.18 |
| liquid 7 | | | | | | | | |
| Dispersion | Pg-1 | 19.4 | Dp-5 | 19.67 | S-1 | 151.53 | 13.27 | 10.18 |
| liquid 8 | | | | | | | | |
| Dispersion | Pg-1 | 19.4 | Dp-6 | 19.67 | S-1 | 151.53 | 13.27 | 10.18 |
| liquid 9 | | | | | | | | |

Details of the materials indicated by the abbreviations in the above table are as follows.

(Pigment)

Pg-1: C. I. Pigment Blue 15:6

Pg-2: C. I. Pigment Red 254

Pg-3: C. I. Pigment Yellow 139

Pg-4: C. I. Pigment Yellow 150

Pg-5: C. I. Pigment Violet 23

(Dispersant)

Dp-1: DISPERBYK-161 (manufactured by BYK Chemie)

Dp-2: resin having the following structure (the numerical value described together with the main chain indicates a molar ratio of the repeating unit; weight-average molecular weight: 11000, acid value: 197 mgKOH/g)

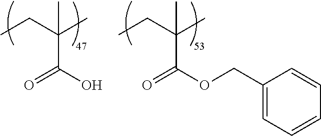

Dp-3 to DP-6: resins having the following structures (weight-average molecular weight of Dp-3 is 12000 and acid value thereof is 46.8 mgKOH/g; weight-average molecular weight of Dp-4 is 14000 and acid value thereof is 31 mgKOH/g; weight-average molecular weight of Dp-5 is 10000 and acid value thereof is 56 mgKOH/g; weight-average molecular weight of Dp-6 is 9000 and acid value thereof is 71 mgKOH/g)

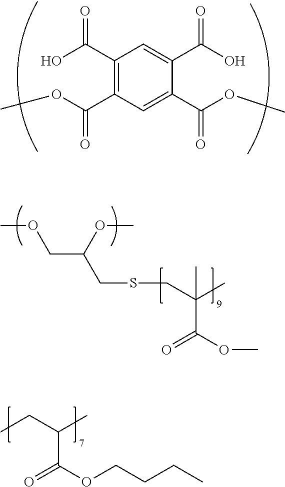

(Solvent)

S-1: propylene glycol monomethyl ether acetate (PGMEA)

<Preparation of Photosensitive Composition>

Raw materials shown in the tables below, 0.0007 parts by mass of a polymerization inhibitor (p-methoxyphenol), 2.50 parts by mass of a fluorine-based surfactant (manufactured by DIC Corporation, MEGAFACE F475, 1% PGMEA solution), and cyclohexanone as a solvent were mixed with each other to obtain a photosensitive composition having a concentration of solid contents of 10.3 mass %. The concentration of solid contents of the photosensitive composition was adjusted by a blending amount of cyclohexanone.

TABLE 2

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 1 | A-1 | 19.22 | Dispersion | 39.6 | I-2 | 0.71 | M-1 | 2 | [symbol] 101 |
| | | | liquid 1 | | | | | | |
| Example 2 | A-1 | 19.22 | Dispersion | 39.6 | I-2 | 0.71 | M-1 | 2 | S [symbol] |
| | | | liquid 1 | | | | | | |
| Example 3 | A-1 | 19. [symbol] 2 | Dispersion | 39.6 | I-2 | 0.71 | M-1 | 2 | Y [symbol] |
| | | | liquid 1 | | | | | | |
| Example 4 | A-1 | 19.22 | Dispersion | 39.6 | I-2 | 0.71 | M-1 | 2 | Ba [symbol] |
| | | | liquid 1 | | | | | | |
| Example 5 | A-1 | 19.22 | Dispersion | 39.6 | I-2 | 0.71 | M-1 | 2 | T [symbol] |
| | | | liquid 1 | | | | | | |
| Example 6 | A-1 | 19.22 | Dispersion | 39.6 | I-2 | 0.71 | M-1 | 2 | S [symbol] |
| | | | liquid 1 | | | | | | |
| Example 7 | A-1 | 19. [symbol] 2 | Dispersion | 39.6 | I-2 | 0.71 | M-1 | 2 | M [symbol] |
| | | | liquid 1 | | | | | | |
| Example 8 | A-1 | 19.22 | Dispersion | 39.6 | I-2 | 0.71 | M-1 | 2 | Ca [symbol] |
| | | | liquid 1 | | | | | | |
| Example 9 | A-1 | 19.22 | Dispersion | 39.6 | I-2 | 0.71 | M-1 | 2 | S [symbol] |
| | | | liquid 1 | | | | | | |
| Example 10 | A-1 | 19.22 | Dispersion | 39.6 | I-2 | 0.71 | M-1 | 2 | C [symbol] |
| | | | liquid 1 | | | | | | |
| Example 11 | A-1 | 19.22 | Dispersion | 39.6 | I-2 | 0.71 | M-1 | 2 | Z [symbol] |
| | | | liquid 1 | | | | | | |
| Example 12 | A-1 | 19.22 | Dispersion | 39.6 | I-2 | 0.71 | M-1 | 2 | L [symbol] |
| | | | liquid 1 | | | | | | |
| Example 13 | A-1 | 19.22 | Dispersion | 39.6 | I-2 | 0.71 | M-1 | 2 | C [symbol] |
| | | | liquid 1 | | | | | | |
| Example 14 | A-1 | 19.22 | Dispersion | 39.6 | I-2 | 0.71 | M-1 | 2 | N [symbol] |
| | | | liquid 1 | | | | | | |
| Example 15 | A-1 | 19.22 | Dispersion | 39.6 | I-2 | 0.71 | M-1 | 2 | Mg [symbol] |
| | | | liquid 1 | | | | | | |
| Example 16 | A-1 | 19.22 | Dispersion | 39.6 | I-2 | 0.71 | M-1 | 2 | C [symbol] |
| | | | liquid 1 | | | | | | |
| Example 17 | A-1 | 19.22 | Dispersion | 39.6 | I-2 | 0.71 | M-1 | 2 | Mg [symbol] |
| | | | liquid 1 | | | | | | |
| Example 18 | A-1 | 19. [symbol] 2 | Dispersion | 39.6 | I-2 | 0.71 | M-1 | 2 | Mg [symbol] |
| | | | liquid 1 | | | | | | |
| Example 19 | A-1 | 19.22 | Dispersion | 39.6 | I-2 | 0.71 | M-1 | 2 | Mg [symbol] |
| | | | liquid 1 | | | | | | |
| Example 20 | A-1 | 19.22 | Dispersion | 39.6 | I-2 | 0.71 | M-1 | 2 | Mg [symbol] |
| | | | liquid 1 | | | | | | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 1 | AN1 | 0.35 | — | — | 0 | P-1 | 1.8 | T-1 | 0. [symbol] |
| | | | | | | P-2 | 0.3 | | |
| Example 2 | AN1 | 0. [symbol] | — | — | 0 | P-1 | 1.8 | T-1 | 0.3 |
| | | | | | | P-2 | 0.3 | | |
| Example 3 | AN1 | 0. [symbol] | — | — | 0 | P-1 | 1.8 | T-1 | 0.3 |
| | | | | | | P-2 | 0.3 | | |
| Example 4 | AN1 | 0. [symbol] | — | — | 0 | P-1 | 1.8 | T-1 | 0.3 |
| | | | | | | P-2 | 0.3 | | |
| Example 5 | AN1 | 0.35 | — | — | 0 | P-1 | 1.8 | T-1 | 0.3 |
| | | | | | | P-2 | 0.3 | | |
| Example 6 | AN1 | 0.35 | — | — | 0 | P-1 | 1.8 | T-1 | 0.3 |
| | | | | | | P-2 | 0.3 | | |
| Example 7 | AN1 | 0. [symbol] | — | — | 0 | P-1 | 1.8 | T-1 | 0.3 |
| | | | | | | P-2 | 0.3 | | |
| Example 8 | AN1 | 0. [symbol] | — | — | 0 | P-1 | 1.8 | T-1 | 0.3 |
| | | | | | | P-2 | 0.3 | | |
| Example 9 | AN1 | 0.35 | — | — | 0 | P-1 | 1.8 | T-1 | 0.3 |
| | | | | | | P-2 | 0.3 | | |
| Example 10 | AN1 | 0.35 | — | — | 0 | P-1 | 1.8 | T-1 | 0.3 |
| | | | | | | P-2 | 0.3 | | |
| Example 11 | AN1 | 0.35 | — | — | 0 | P-1 | 1.8 | T-1 | 0. [symbol] |
| | | | | | | P-2 | 0.3 | | |
| Example 12 | AN1 | 0. [symbol] | — | — | 0 | P-1 | 1.8 | T-1 | 0.3 |
| | | | | | | P-2 | 0.3 | | |
| Example 13 | AN1 | 0. [symbol] | — | — | 0 | P-1 | 1.8 | T-1 | 0.3 |
| | | | | | | P-2 | 0.3 | | |
| Example 14 | AN1 | 0. [symbol] | — | — | 0 | P-1 | 1.8 | T-1 | 0.3 |
| | | | | | | P-2 | 0.3 | | |
| Example 15 | AN17 | 0.35 | — | — | 0 | P-1 | 1.8 | T-1 | 0.3 |
| | | | | | | P-2 | 0.3 | | |
| Example 16 | AN19 | 0.35 | — | — | 0 | P-1 | 1.8 | T-1 | 0. [symbol] |
| | | | | | | P-2 | 0.3 | | |
| Example 17 | AN2 | 0.35 | — | — | 0 | P-1 | 1.8 | T-1 | 0. [symbol] |
| | | | | | | P-2 | 0.3 | | |
| Example 18 | AN7 | 0. [symbol] | — | — | 0 | P-1 | 1.8 | T-1 | 0.3 |
| | | | | | | P-2 | 0.3 | | |
| Example 19 | AN11 | 0.35 | — | — | 0 | P-1 | 1.8 | T-1 | 0.3 |
| | | | | | | P-2 | 0.3 | | |
| Example 20 | AN15 | 0.35 | — | — | 0 | P-1 | 1.8 | T-1 | 0. [symbol] |
| | | | | | | P-2 | 0.3 | | |

[symbol]

indicates data missing or illegible when filed

TABLE 3

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 21 | A-1 | 19. [symbol] 2 | Dispersion | 39.6 | I-2 | 0.71 | M-1 | 2 | Mg [symbol] |
| | | | liquid 1 | | | | | | |
| Example 22 | A-1 | 19.22 | Dispersion | 39.6 | I-2 | 0.71 | M-1 | 2 | Mg [symbol] |
| | | | liquid 1 | | | | | | |
| Example 23 | A-1 | 19.22 | Dispersion | 39.6 | I-2 | 0.71 | M-1 | 2 | Mg [symbol] |
| | | | liquid 1 | | | | | | |
| Example 24 | A-1 | 19.22 | Dispersion | 39.6 | I-2 | 0.71 | M-1 | 2 | Mg [symbol] |
| | | | liquid 1 | | | | | | |
| Example 25 | A-1 | 19.22 | Dispersion | 39.6 | I-2 | 0.71 | M-1 | 2 | Mg [symbol] |
| | | | liquid 1 | | | | | | |
| Example 26 | A-1 | 19.22 | Dispersion | 39.6 | I-2 | 0.71 | M-1 | 2 | Mg [symbol] |
| | | | liquid 1 | | | | | | |
| Example 27 | A-1 | 19.2 [symbol] | Dispersion | 39.6 | I- [symbol] | 0. [symbol] 1 | M-1 | 2 | Mg [symbol] |
| | | | liquid 1 | | | | | | |
| Example 28 | A-1 | 19. [symbol] 2 | Dispersion | [symbol] 9.6 | I-2 | 0.71 | M-1 | 2 | Mg [symbol] |
| | | | liquid 1 | | | | | | |
| Example 29 | A-1 | 19.22 | Dispersion | 39.6 | I-2 | 0.71 | M-1 | 2 | Mg [symbol] |
| | | | liquid 1 | | | | | | |
| Example 30 | A-1 | 19.22 | Dispersion | 3 [symbol] . [symbol] | I-2 | 0.71 | M-1 | 2 | Mg [symbol] |
| | | | liquid 1 | | | | | | |
| Example 31 | A-1 | 19.22 | Dispersion | 39.6 | I-2 | 0.71 | M-1 | 2 | Mg [symbol] |
| | | | liquid 1 | | | | | | |
| Example 32 | A-1 | 19. [symbol] 2 | Dispersion | 39.6 | I-2 | 0.71 | M-1 | 2 | Mg [symbol] |
| | | | liquid 1 | | | | | | |
| Example 33 | A-1 | 19. [symbol] 2 | Dispersion | 39.6 | I-2 | 0.71 | M-1 | 2 | Mg [symbol] |
| | | | liquid 1 | | | | | | |
| Example 34 | A-1 | 19.2 [symbol] | Dispersion | 39. [symbol] | I-2 | 0.71 | M-1 | 2 | L [symbol] |
| | | | liquid 1 | | | | | | |
| Example 35 | A-1 | 19.22 | Dispersion | 39.6 | I-2 | 0.71 | M-1 | 2 | L [symbol] |
| | | | liquid 1 | | | | | | |
| Example 36 | A-1 | 1 [symbol] . [symbol] 2 | Dispersion | 39.6 | I-2 | 0.71 | M-1 | 2 | L [symbol] |
| | | | liquid 1 | | | | | | |
| Example 37 | A-1 | 19.22 | Dispersion | 39.6 | I-2 | 0.71 | M-1 | 2 | L [symbol] |
| | | | liquid 1 | | | | | | |
| Example 38 | A-1 | 19.22 | Dispersion | 3 [symbol] .6 | I-2 | 0.71 | M-1 | 2 | C [symbol] |
| | | | liquid 1 | | | | | | |
| Example 39 | A-1 | 19.22 | Dispersion | 39.6 | I-2 | 0.71 | M-1 | 2 | Zn [symbol] |
| | | | liquid 1 | | | | | | |
| Example 40 | A-1 | 19.22 | Dispersion | 39.6 | I-2 | 0.71 | M-1 | 2 | L [symbol] |
| | | | liquid 1 | | | | | | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 21 | AN1 [symbol] | 0. [symbol] | — | — | 0 | P-1 | 1.8 | T-1 | 0.3 |
| | | | | | | P-2 | 0.3 | | |
| Example 22 | AN31 | 0.35 | — | — | 0 | P-1 | 1.8 | T-1 | 0.3 |
| | | | | | | P-2 | 0.3 | | |
| Example 23 | AN3 [symbol] | 0.35 | — | — | 0 | P-1 | 1.8 | T-1 | 0.3 |
| | | | | | | P-2 | 0.3 | | |
| Example 24 | AN24 | 0.35 | — | — | 0 | P-1 | 1.8 | T-1 | 0.3 |
| | | | | | | P-2 | 0.3 | | |
| Example 25 | AN25 | 0.35 | — | — | 0 | P-1 | 1.8 | T-1 | 0.3 |
| | | | | | | P-2 | 0.3 | | |
| Example 26 | AN26 | 0.35 | — | — | 0 | P-1 | 1.8 | T-1 | 0.3 |
| | | | | | | P-2 | 0.3 | | |
| Example 27 | AN27 | 0.35 | — | — | 0 | P-1 | 1.8 | T-1 | 0. [symbol] |
| | | | | | | P-2 | 0.3 | | |
| Example 28 | AN28 | 0.35 | — | — | 0 | P-1 | 1.8 | T-1 | 0.3 |
| | | | | | | P-2 | 0.3 | | |
| Example 29 | AN2 [symbol] | 0.3 [symbol] | — | — | 0 | P-1 | 1.8 | T-1 | 0.3 |
| | | | | | | P-2 | 0.3 | | |
| Example 30 | AN30 | 0.35 | — | — | 0 | P-1 | 1.8 | T-1 | 0.3 |
| | | | | | | P-2 | 0.3 | | |
| Example 31 | AN21 | 0.35 | — | — | 0 | P-1 | 1.8 | T-1 | 0.3 |
| | | | | | | P-2 | 0.3 | | |
| Example 32 | AN22 | 0. [symbol] | — | — | 0 | P-1 | 1.8 | T-1 | 0.3 |
| | | | | | | P-2 | 0.3 | | |
| Example 33 | AN2 [symbol] | 0.35 | — | — | 0 | P-1 | 1.8 | T-1 | 0.3 |
| | | | | | | P-2 | 0.3 | | |
| Example 34 | AN24 | 0.35 | — | — | 0 | P-1 | 1.8 | T-1 | 0.3 |
| | | | | | | P-2 | 0.3 | | |
| Example 35 | AN2 [symbol] | 0.35 | — | — | 0 | P-1 | 1.8 | T-1 | 0.3 |
| | | | | | | P-2 | 0.3 | | |
| Example 36 | AN26 | 0. [symbol] 5 | — | — | 0 | P-1 | 1.8 | T-1 | 0.3 |
| | | | | | | P-2 | 0.3 | | |
| Example 37 | AN27 | 0.35 | — | — | 0 | P-1 | 1.8 | T-1 | 0.3 |
| | | | | | | P-2 | 0.3 | | |
| Example 38 | AN25 | 0.3 [symbol] | — | — | 0 | P-1 | 1.8 | T-1 | 0.3 |
| | | | | | | P-2 | 0.3 | | |
| Example 39 | AN25 | 0.35 | — | — | 0 | P-1 | 1.8 | T-1 | 0.3 |
| | | | | | | P-2 | 0.3 | | |
| Example 40 | AN2 [symbol] | 0. [symbol] 5 | — | — | 0 | P-1 | 1.8 | T-1 | 0.3 |
| | | | | | | P-2 | 0.3 | | |

[symbol]

indicates data missing or illegible when filed

TABLE 4

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 41 | A-1 | 19.22 | Dispersion | [symbol] 9.6 | I-2 | 0.71 | M-1 | 2 | C [symbol] |
| | | | liquid 1 | | | | | | |
| Example 42 | A-1 | 19.22 | Dispersion | 39.6 | I-2 | 0.71 | M-1 | 2 | N [symbol] |
| | | | liquid 1 | | | | | | |
| Example 43 | A-1 | 19.22 | Dispersion | 39.6 | I-2 | 0.71 | M-1 | 2 | S [symbol] |
| | | | liquid 1 | | | | | | |
| Example 44 | A-1 | 19. [symbol] 2 | Dispersion | 39.6 | I-2 | 0.71 | M-1 | 2 | Y [symbol] |
| | | | liquid 1 | | | | | | |
| Example 45 | A-1 | 19.22 | Dispersion | 39.6 | I-2 | 0.71 | M-1 | 2 | B [symbol] |
| | | | liquid 1 | | | | | | |
| Example 46 | A-1 | 19.22 | Dispersion | 3 [symbol] .6 | I-2 | 0.71 | M-1 | 2 | T [symbol] |
| | | | liquid 1 | | | | | | |
| Example 47 | A-1 | 19.22 | Dispersion | 39.6 | I-2 | 0.71 | M-1 | 2 | S [symbol] |
| | | | liquid 1 | | | | | | |
| Example 48 | A-1 | 19.2 [symbol] | Dispersion | 39.6 | I-2 | 0.71 | M-1 | [symbol] | N [symbol] |
| | | | liquid 1 | | | | | | |
| Example 49 | A-1 | 19.22 | Dispersion | 39.6 | I-2 | 0.71 | M-1 | 2 | Y [symbol] |
| | | | liquid 1 | | | | | | |
| Example 50 | A-1 | 19.22 | Dispersion | 39.6 | I-2 | 0.71 | M-1 | 2 | H [symbol] |
| | | | liquid 1 | | | | | | |
| Example 51 | A-1 | 19.22 | Dispersion | 39.6 | I-2 | 0.71 | M-1 | 2 | T [symbol] |
| | | | liquid 1 | | | | | | |
| Example 52 | A-1 | 19.22 | Dispersion | 39.6 | I-2 | 0.71 | M-1 | 2. [symbol] | Mg [symbol] |
| | | | liquid 1 | | | | | | |
| Example 53 | A-1 | 19.22 | Dispersion | 39.6 | I-2 | 0.71 | M-1 | 2.2 | Mg [symbol] |
| | | | liquid 1 | | | | | | |
| Example 54 | A-1 | 19.22 | Dispersion | 39.6 | I-2 | 0.71 | M-1 | 2.1 | Mg [symbol] |
| | | | liquid 1 | | | | | | |
| Example 55 | A-1 | 19.22 | Dispersion | 39.6 | I-2 | 0.71 | M-1 | 1.8 | Mg [symbol] |
| | | | liquid 1 | | | | | | |
| Example 56 | A-1 | 19.2 [symbol] | Dispersion | 3 [symbol] .6 | I-2 | 0.71 | M-1 | 1.6 [symbol] | Mg [symbol] |
| | | | liquid 1 | | | | | | |
| Example 57 | A-1 | 19. [symbol] 2 | Dispersion | [symbol] 9.6 | I-2 | 0.71 | M-1 | 2.25 | L [symbol] |
| | | | liquid 1 | | | | | | |
| Example 58 | A-1 | 19.22 | Dispersion | 39.6 | I-2 | 0.71 | M-1 | 2.2 | L [symbol] |
| | | | liquid 1 | | | | | | |
| Example 59 | A-1 | 19.22 | Dispersion | 39.6 | I-2 | 0.71 | M-1 | [symbol] .1 | L [symbol] |
| | | | liquid 1 | | | | | | |
| Example 60 | A-1 | 19.22 | Dispersion | 39.6 | I-2 | 0.71 | M-1 | 1.8 | L [symbol] |
| | | | liquid 1 | | | | | | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 41 | AN25 | 0.35 | — | — | 0 | P-1 | 1.8 | T-1 | 0.3 |
| | | | | | | P-2 | 0.3 | | |
| Example 42 | AN25 | 0.3 [symbol] | — | — | 0 | P-1 | 1.8 | T-1 | 0.3 |
| | | | | | | P-2 | 0.3 | | |
| Example 43 | AN25 | 0.35 | — | — | 0 | P-1 | 1.8 | T-1 | 0.3 |
| | | | | | | P-2 | 0.3 | | |
| Example 44 | AN2 [symbol] | 0.35 | — | — | 0 | P-1 | 1.8 | T-1 | 0.3 |
| | | | | | | P-2 | 0.3 | | |
| Example 45 | AN25 | 0.3 [symbol] | — | — | 0 | P-1 | 1.8 | T-1 | 0.3 |
| | | | | | | P-2 | 0.3 | | |
| Example 46 | AN25 | 0.35 | — | — | 0 | P-1 | 1.8 | T-1 | 0.3 |
| | | | | | | P-2 | 0.3 | | |
| Example 47 | AN25 | 0.3 [symbol] | — | — | 0 | P-1 | 1.8 | T-1 | 0.3 |
| | | | | | | P-2 | 0.3 | | |
| Example 48 | AN25 | 0.35 | — | — | 0 | P-1 | 1.8 | T-1 | 0. [symbol] |
| | | | | | | P-2 | 0.3 | | |
| Example 49 | AN25 | 0. [symbol] 5 | — | — | 0 | P-1 | 1.8 | T-1 | 0.3 |
| | | | | | | P-2 | 0.3 | | |
| Example 50 | AN25 | 0.35 | — | — | 0 | P-1 | 1.8 | T-1 | 0.3 |
| | | | | | | P-2 | 0.3 | | |
| Example 51 | AN25 | 0.35 | — | — | 0 | P-1 | 1.8 | T-1 | 0.3 |
| | | | | | | P-2 | 0.3 | | |
| Example 52 | AN25 | 0.1 | — | — | 0 | P-1 | 1.8 | T-1 | 0.3 |
| | | | | | | P-2 | 0.3 | | |
| Example 53 | AN25 | 0.15 | — | — | 0 | P-1 | 1.8 | T-1 | 0.3 |
| | | | | | | P-2 | 0.3 | | |
| Example 54 | AN25 | 0.25 | — | — | 0 | P-1 | 1.8 | T-1 | 0.3 |
| | | | | | | P-2 | 0.3 | | |
| Example 55 | AN25 | 0. [symbol] 5 | — | — | 0 | P-1 | 1.8 | T-1 | 0.3 |
| | | | | | | P-2 | 0.3 | | |
| Example 56 | AN25 | 0.7 | — | — | 0 | P-1 | 1.8 | T-1 | 0.3 |
| | | | | | | P-2 | 0.3 | | |
| Example 57 | AN25 | 0.1 | — | — | 0 | P-1 | 1.8 | T-1 | 0.3 |
| | | | | | | P-2 | 0.3 | | |
| Example 58 | AN25 | 0.15 | — | — | 0 | P-1 | 1.8 | T-1 | 0.3 |
| | | | | | | P-2 | 0.3 | | |
| Example 59 | AN25 | 0.25 | — | — | 0 | P-1 | 1.8 | T-1 | 0.3 |
| | | | | | | P-2 | 0.3 | | |
| Example 60 | AN25 | 0.5 [symbol] | — | — | 0 | P-1 | 1.8 | T-1 | 0.3 |
| | | | | | | P-2 | 0.3 | | |

[symbol]

indicates data missing or illegible when filed

TABLE 5

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 61 | A-1 | 19. [symbol] | Dispersion | 39. [symbol] | I- [symbol] | 0.71 | M-1 | 1. [symbol] | L [symbol] |
| | | | liquid 1 | | | | | | |
| Example 62 | A-2 | 19.22 | Dispersion | 39.6 | I-2 | 0.71 | M-1 | 2 | Mg [symbol] |
| | | | liquid 1 | | | | | | |
| Example 63 | A-3 | 19.22 | Dispersion | 39. [symbol] | I-2 | 0.71 | M-1 | 2 | Mg [symbol] |
| | | | liquid 1 | | | | | | |
| Example 64 | A-4 | 19.22 | Dispersion | 39.6 | I-2 | 0.71 | M-1 | 2 | Mg [symbol] |
| | | | liquid 1 | | | | | | |
| Example 65 | A-5 | 19.22 | Dispersion | 39.6 | I-2 | 0.71 | M-1 | 2 | Mg [symbol] |
| | | | liquid 1 | | | | | | |
| Example 66 | A-5 | 19.22 | Dispersion | 39.6 | I-2 | 0.71 | M-1 | 2 | Z [symbol] |
| | | | liquid 1 | | | | | | |
| Example 67 | A-5 | 19.22 | Dispersion | 39.6 | I-2 | 0.71 | M-1 | 2 | L [symbol] |
| | | | liquid 1 | | | | | | |
| Example 68 | A-5 | 19.22 | Dispersion | 39.6 | I-2 | 0.71 | M-1 | 2 | C [symbol] |
| | | | liquid 1 | | | | | | |
| Example 69 | A-6 | 19.22 | Dispersion | 39.6 | I-2 | 0.71 | M-1 | 2 | Mg [symbol] |
| | | | liquid 1 | | | | | | |
| Example 70 | A-7 | 19.22 | Dispersion | 39.6 | I-2 | 0.71 | M-1 | 2 | Mg [symbol] |
| | | | liquid 1 | | | | | | |
| Example 71 | A-8 | 19.22 | Dispersion | 39.6 | I-2 | 0.71 | M-1 | 2 | Mg [symbol] |
| | | | liquid 1 | | | | | | |
| Example 72 | A-1 | 19.2 [symbol] | Dispersion | 39.6 | I-2 | 0.71 | M-1 | 2 | Mg [symbol] |
| | | | liquid 1 | | | | | | |
| Example 73 | A-1 | 19.22 | Dispersion | 39.6 | I-2 | 0.71 | M-1 | 2 | Mg [symbol] |
| | | | liquid 1 | | | | | | |
| Example 74 | A-1 | 19.22 | Dispersion | 39.6 | I-2 | 0.71 | M-1 | 2 | Mg [symbol] |
| | | | liquid 1 | | | | | | |
| Example 75 | A-1 | 19.22 | Dispersion | 3 [symbol] . [symbol] | I-2 | 0.71 | M-1 | 2 | Mg [symbol] |
| | | | liquid 1 | | | | | | |
| Example 76 | A-1 | 19.22 | Dispersion | 39.6 | I-2 | 0.71 | M-1 | 2 | Mg [symbol] |
| | | | liquid 1 | | | | | | |
| Example 77 | A-1 | 19.22 | Dispersion | 39.6 | I-2 | 0.71 | M-1 | 2 | Mg [symbol] |
| | | | liquid 1 | | | | | | |
| Example 78 | A-1 | 19.22 | Dispersion | 39.6 | I-2 | 0.71 | M-1 | 2 | Mg [symbol] |
| | | | liquid 1 | | | | | | |
| Example 79 | A-1 | 19.22 | Dispersion | 39.6 | I-2 | 0.71 | M-1 | 2 | Mg [symbol] |
| | | | liquid 1 | | | | | | |
| Example 80 | A-1 | 19.22 | Dispersion | 39.6 | I-2 | 0.71 | M-1 | 2 | Mg [symbol] |
| | | | liquid 1 | | | | | | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 61 | AN [symbol] | 0.7 | — | — | 0 | P-1 | 1.8 | T-1 | 0.3 |
| | | | | | | P-2 | 0.3 | | |
| Example 62 | AN25 | 0.35 | — | — | 0 | P-1 | 1.8 | T-1 | 0.3 |
| | | | | | | P-2 | 0.3 | | |
| Example 63 | AN [symbol] | 0.35 | — | — | 0 | P-1 | 1.8 | T-1 | 0.3 |
| | | | | | | P-2 | 0.3 | | |
| Example 64 | AN [symbol] | 0.35 | — | — | 0 | P-1 | 1.8 | T-1 | 0.3 |
| | | | | | | P-2 | 0.3 | | |
| Example 65 | AN25 | 0.35 | — | — | 0 | P-1 | 1.8 | T-1 | 0.3 |
| | | | | | | P-2 | 0.3 | | |
| Example 66 | AN25 | 0.35 | — | — | 0 | P-1 | 1.8 | T-1 | 0.3 |
| | | | | | | P-2 | 0.3 | | |
| Example 67 | AN25 | 0.35 | — | — | 0 | P-1 | 1.8 | T-1 | 0.3 |
| | | | | | | P-2 | 0.3 | | |
| Example 68 | AN25 | 0.35 | — | — | 0 | P-1 | 1.8 | T-1 | 0.3 |
| | | | | | | P-2 | 0.3 | | |
| Example 69 | AN25 | 0.35 | — | — | 0 | P-1 | 1.8 | T-1 | 0.3 |
| | | | | | | P-2 | 0.3 | | |
| Example 70 | AN25 | 0.35 | — | — | 0 | P-1 | 1.8 | T-1 | 0.3 |
| | | | | | | P-2 | 0.3 | | |
| Example 71 | AN25 | 0.35 | — | — | 0 | P-1 | 1.8 | T-1 | 0.3 |
| | | | | | | P-2 | 0.3 | | |
| Example 72 | AN [symbol] 7 | 0.35 | — | — | 0 | P-1 | 1.8 | T-1 | 0.3 |
| | | | | | | P-2 | 0.3 | | |
| Example 73 | AN27 | 0.35 | — | — | 0 | P-1 | 1.8 | T-2 | 0.3 |
| | | | | | | P-2 | 0.3 | | |
| Example 74 | AN27 | 0.35 | — | — | 0 | P-1 | 1.8 | T-3 | 0.3 |
| | | | | | | P-2 | 0.3 | | |
| Example 75 | AN27 | 0.35 | — | — | 0 | P-1 | 1.8 | T-4 | 0.3 |
| | | | | | | P-2 | 0.3 | | |
| Example 76 | AN27 | 0.35 | — | — | 0 | P-1 | 1.8 | T-1 | 0.1 |
| | | | | | | P-2 | 0.3 | | |
| Example 77 | AN27 | 0.35 | — | — | 0 | P-1 | 1.8 | T-1 | 0.2 |
| | | | | | | P-2 | 0.3 | | |
| Example 78 | AN27 | 0. [symbol] 5 | — | — | 0 | P-1 | 1.8 | T-1 | 0.4 |
| | | | | | | P-2 | 0.3 | | |
| Example 79 | AN27 | 0.3 [symbol] | — | — | 0 | P-1 | 1.8 | T-1 | 0. [symbol] |
| | | | | | | P-2 | 0.3 | | |
| Example 80 | AN27 | 0.35 | — | — | 0 | P-1 | 1.8 | T-1 | 0. [symbol] |
| | | | | | | P-2 | 0.3 | | |

[symbol]

indicates data missing or illegible when filed

TABLE 6

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 81 | A-1 | 19.22 | Dispersion | 39.6 | I-2 | 0.71 | M-1 | 1.65 | Mg [symbol] |
| | | | liquid 5 | | | | | | |
| Example 82 | A-1 | 19.22 | Dispersion | 39.6 | I-2 | 0.71 | M-1 | 2 | Mg [symbol] |
| | | | liquid 5 | | | | | | |
| Example 83 | A-1 | 19.22 | Dispersion | 3 [symbol] . [symbol] | I-2 | 0.71 | M-1 | 2 | Mg [symbol] |
| | | | liquid 5 | | | | | | |
| Example 84 | A-1 | 19.22 | Dispersion | 39.6 | I-2 | 0.71 | M-1 | 2 | Mg [symbol] |
| | | | liquid 5 | | | | | | |
| Example 85 | A-1 | 19.22 | Dispersion | 39.6 | I-2 | 0.71 | M-1 | 2 | Mg [symbol] |
| | | | liquid 5 | | | | | | |
| Example 86 | A-1 | 19.22 | Dispersion | 39. [symbol] | I- [symbol] | 0.71 | M-1 | 2 | Mg [symbol] |
| | | | liquid 5 | | | | | | |
| Example 87 | A-1 | 19.22 | Dispersion | 39.6 | I- [symbol] | 0.71 | M-1 | [symbol] | Mg [symbol] |
| | | | liquid [symbol] | | | | | | |
| Example 88 | A-1 | 19.22 | Dispersion | 39.6 | I-5 | 0.71 | M-1 | 2 | Mg [symbol] |
| | | | liquid 5 | | | | | | |
| Example 89 | A-1 | 19.2 [symbol] | Dispersion | 39.6 | I-6 | 0.71 | M-1 | 2 | Mg [symbol] |
| | | | liquid 5 | | | | | | |
| Example 90 | A-1 | 19.22 | Dispersion | 39.6 | I-3 | 0.71 | M-1 | 2 | Mg [symbol] |
| | | | liquid 6 | | | | | | |
| Example 91 | A-1 | 19.22 | Dispersion | 39.6 | I-3 | 0.71 | M-1 | 2 | Mg [symbol] |
| | | | liquid 7 | | | | | | |
| Example 92 | A-1 | 19.22 | Dispersion | 39.6 | I-3 | 0.71 | M-1 | 2 | Mg [symbol] |
| | | | liquid 8 | | | | | | |
| Example 93 | A-1 | 19.22 | Dispersion | 39.6 | I-3 | 0.71 | M-1 | 2 | Mg [symbol] |
| | | | liquid 9 | | | | | | |
| Example 94 | A-1 | 19.22 | Dispersion | 39.6 | I-2 | 0.71 | M-1 | 2 | Y [symbol] |
| | | | liquid 1 | | | | | | |
| Example 95 | A-1 | 19.22 | Dispersion | 39.6 | I-2 | 0.71 | M-1 | 2 | L [symbol] |
| | | | liquid 1 | | | | | | |
| Example 96 | A-1 | 19.22 | Dispersion | 39.6 | I-2 | 0.71 | M-1 | 2 | Zn [symbol] |
| | | | liquid 1 | | | | | | |
| Example 97 | A-1 | 19.22 | Dispersion | 39.6 | I-2 | 0.71 | M-1 | 2 | L [symbol] |
| | | | liquid 1 | | | | | | |
| Example 98 | A-1 | 19.22 | Dispersion | 39.6 | I-2 | 0.71 | M-1 | 1 | L [symbol] |
| | | | liquid 1 | | | | M-2 | 1 | |
| Example 99 | A-1 | 19.22 | Dispersion | 39.6 | I-2 | 0.71 | M-1 | 1 | Mg [symbol] |
| | | | liquid 1 | | | | M-3 | 1 | |
| Example 100 | A-1 | 19.22 | Dispersion | 39.6 | I-2 | 0.71 | M-1 | 1 | Mg [symbol] |
| | | | liquid 1 | | | | M-4 | 1 | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 81 | AN2 [symbol] | 0.35 | — | — | 0 | P-1 | 1. [symbol] | T-1 | 0.3 |
| | | | | | | P-2 | 0.3 | | |
| Example 82 | AN25 | 0. [symbol] 5 | — | — | 0 | P-1 | 1.8 | T-1 | 0.3 |
| | | | | | | P-2 | 0.3 | | |
| Example 83 | AN26 | 0.35 | — | — | 0 | P-1 | 1.8 | T-1 | 0.3 |
| | | | | | | P-2 | 0.3 | | |
| Example 84 | AN27 | 0.35 | — | — | 0 | P-1 | 1.8 | T-1 | 0.3 |
| | | | | | | P-2 | 0.3 | | |
| Example 85 | AN28 | 0.35 | — | — | 0 | P-1 | 1.8 | T-1 | 0.3 |
| | | | | | | P-2 | 0.3 | | |
| Example 86 | AN2 [symbol] | 0.35 | — | — | 0 | P-1 | 1.8 | T-1 | 0.3 |
| | | | | | | P-2 | 0.3 | | |
| Example 87 | AN28 | 0.35 | — | — | 0 | P-1 | 1.8 | T-1 | 0.3 |
| | | | | | | P-2 | 0.3 | | |
| Example 88 | AN28 | 0. [symbol] | — | — | 0 | P-1 | 1.8 | T-1 | 0.3 |
| | | | | | | P-2 | 0.3 | | |
| Example 89 | AN [symbol] | 0.3 [symbol] | — | — | 0 | P-1 | 1.8 | T-1 | 0.3 |
| | | | | | | P-2 | 0.3 | | |
| Example 90 | AN28 | 0.35 | — | — | 0 | P-1 | 1.8 | T-1 | 0.3 |
| | | | | | | P-2 | 0.3 | | |
| Example 91 | AN28 | 0.35 | — | —— | 0 | P-1 | 1.8 | T-1 | 0. [symbol] |
| | | | | | | P-2 | 0.3 | | |
| Example 92 | AN28 | 0.35 | — | — | 0 | P-1 | 1. [symbol] | T-1 | 0.3 |
| | | | | | | P-2 | 0.3 | | |
| Example 93 | AN28 | 0.35 | — | — | 0 | P-1 | 1.8 | T-2 | 0.3 |
| | | | | | | P-2 | 0.3 | | |
| Example 94 | AN1 | 0.20 | S [symbol] | AN1 | 0.15 | P-1 | 1.8 | T-3 | 0.3 |
| | | | | | | P-2 | 0. [symbol] | | |
| Example 95 | AN2 [symbol] | 0.20 | Y [symbol] | AN1 | 0.15 | P-1 | 1.8 | T-4 | 0.3 |
| | | | | | | P-2 | 0.3 | | |
| Example 96 | AN25 | 0.20 | Y [symbol] | AN1 | 0.15 | P-1 | 1.8 | T-1 | 0.1 |
| | | | | | | P-2 | 0.3 | | |
| Example 97 | AN27 | 0.20 | E101 | AN1 | 0.15 | P-1 | 1.8 | T-1 | 0.2 |
| | | | | | | P-2 | 0.3 | | |
| Example 98 | AN2 [symbol] | 0.20 | Sn [symbol] | AN1 | 0.15 | P-1 | 1.8 | T-1 | 0.4 |
| | | | | | | P-2 | 0.3 | | |
| Example 99 | AN2 [symbol] | 0.35 | — | — | 0 | P-1 | 1.8 | T-1 | 0. [symbol] |
| | | | | | | P-2 | 0.3 | | |
| Example 100 | AN26 | 0.35 | — | — | 0 | P-1 | 1.8 | T-1 | 0.6 |
| | | | | | | P-2 | 0.3 | | |

[symbol]

indicates data missing or illegible when filed

TABLE 7

| | Dye | | Pigment | | Photopolymerization | | Polymerizable | | |
|---|---|---|---|---|---|---|---|---|---|
| | solution | | dispersion liquid | | initiator | | compound | | Specific |
| | | Blending | | Blending | | Blending | | Blending | compound 1 |
| | | amount | | amount | | amount | | amount | Type of |
| | Type | (part by mass) | Type | (part by mass) | Type | (part by mass) | Type | (part by mass) | [symbol] |
| Example 101 | A-1 | 19.22 | Dispersion | 39.6 | I-2 | 0.71 | M-1 | 2 | Mg [symbol] |
| | | | liquid 1 | | | | | | |
| Example 102 | A-1 | 19.22 | Dispersion | [symbol] .6 | I-2 | 0.71 | M-1 | 2 | Mg [symbol] |
| | | | liquid 1 | | | | | | |
| Example 103 | A-1 | 19.22 | Dispersion | 39.6 | I-2 | 0.71 | M-2 | 1 | Mg [symbol] |
| | | | liquid 1 | | | | M- [symbol] | 1 | |
| Example 104 | A-1 | 19.22 | Dispersion | 26.4 | I-2 | 0.71 | M-1 | 2 | Mg [symbol] |
| | | | liquid 2 | 13.2 | | | | | |
| | | | Dispersion | | | | | | |
| | | | liquid 3 | | | | | | |
| Comparative | A-8 | 19.22 | Dispersion | 39.6 | I-3 | 0.71 | M-1 | 2 | None |
| Example 1 | | | liquid [symbol] | | | | | | |
| Comparative | A-8 | 19.22 | Dispersion | 39.6 | I-3 | 0.71 | M-1 | 2 | NH [symbol] |
| Example 2 | | | liquid 5 | | | | | | |
| Comparative | A-8 | 19.22 | Dispersion | 39.6 | I-3 | 0.71 | M-1 | 2 | N (CH [symbol] ) [symbol] |
| Example 3 | | | liquid 5 | | | | | | |

| | Specific | | Specific | | | | | Thermosetting | |
|---|---|---|---|---|---|---|---|---|---|
| | compound 1 | | compound 2 | | | Resin | | agent | |
| | | Blending | | | Blending | | Blending | | Blending |
| | Type of | amount | Type of | Type of | amount | | amount | | amount |
| | [symbol] | (part by mass) | [symbol] | [symbol] | (part by mass) | Type | (part by mass) | Type | (part by mass) |
| Example 101 | AN26 | 0. [symbol] | — | — | 0 | P-1 | 1.8 | T-1 | 0.3 |
| | | | | | | P-2 | 0.3 | | |
| Example 102 | AN26 | 0.35 | — | — | 0 | P-1 | 1.8 | T-1 | 0.3 |
| | | | | | | P-2 | 0.3 | | |
| Example 103 | AN26 | 0. [symbol] | — | — | 0 | P-1 | 1.8 | T-1 | 0.3 |
| | | | | | | P-2 | 0.3 | | |
| Example 104 | AN24 | 0.35 | — | — | 0 | P-1 | 1.8 | T-1 | 0.3 |
| | | | | | | P-2 | 0.3 | | |
| Comparative | None | 0.35 | — | — | 0 | P-1 | 1.8 | T-1 | 0.3 |
| Example 1 | | | | | | P-2 | 0.3 | | |
| Comparative | AN1 | 0.35 | — | — | 0 | P-1 | 1.8 | T-1 | 0.3 |
| Example 2 | | | | | | P-2 | 0.3 | | |
| Comparative | AN [symbol] | 0.35 | — | — | 0 | P-1 | 1.8 | T-1 | 0.3 |
| Example 3 | | | | | | P- [symbol] | 0.3 | | |

[symbol]

indicates data missing or illegible when filed

Details of the materials indicated by the abbreviations in the above table are as follows.

(Dye Solution)

A-1: cyclohexanone solution (solid content: 12.3 mass %) of a dye having the following structure (magenta dye having a xanthene coloring agent structure; weight-average molecular weight: 7000);

in the following structural formula, n is 3 and m is 3

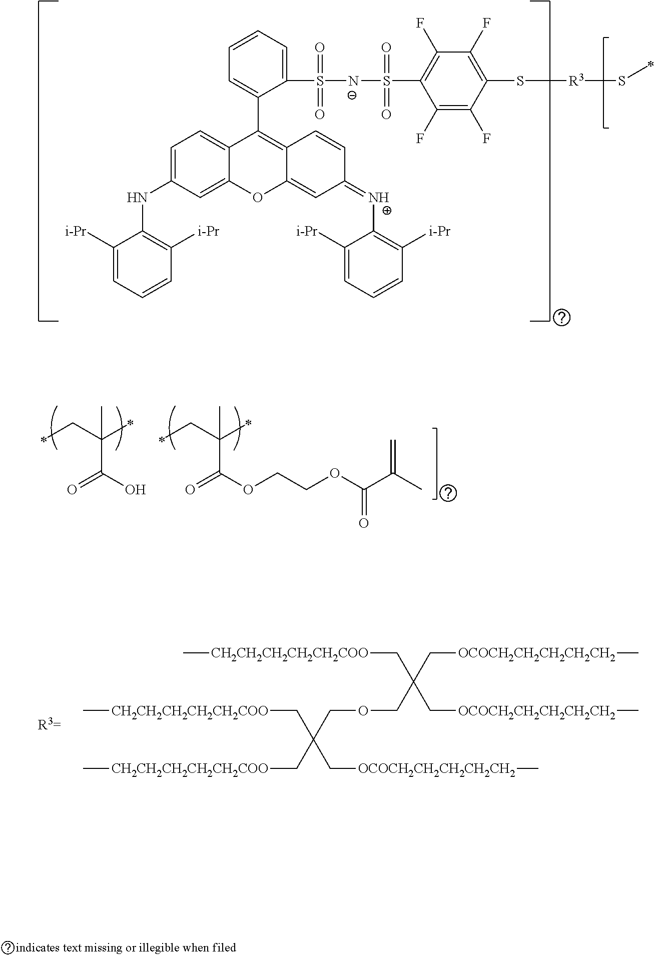

A-2: cyclohexanone solution (solid content: 12.3 mass %) of a dye having the following structure (magenta dye having a xanthene coloring agent structure; molecular weight: 704.24)

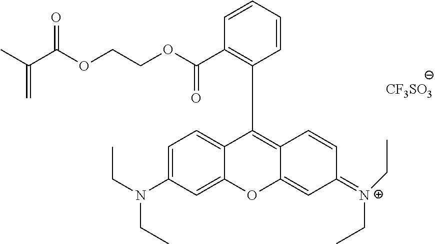 [SMILES: C=C(C)C(=O)OCCOC(=O)c1ccccc1Cc1c2ccc(=[N+](CC)CC)cc-2oc2cc(N(CC)CC)ccc12 ; "CF3SO3"]

A-3: cyclohexanone solution (solid content: 12.3 mass %) of a dye having the following structure (magenta dye having a xanthene coloring agent structure; weight-average molecular weight: 10000)

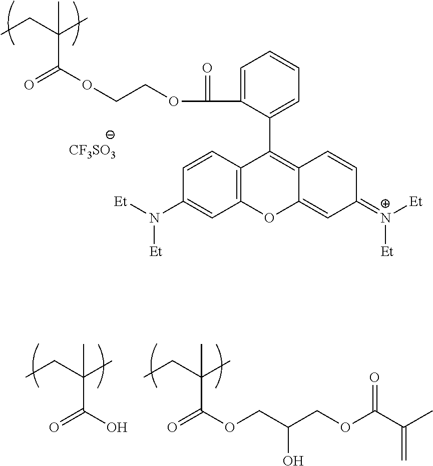

A-4: cyclohexanone solution (solid content: 12.3 mass %) of a dye having the following structure (magenta dye having a xanthene coloring agent structure; molecular weight: 1115.28)

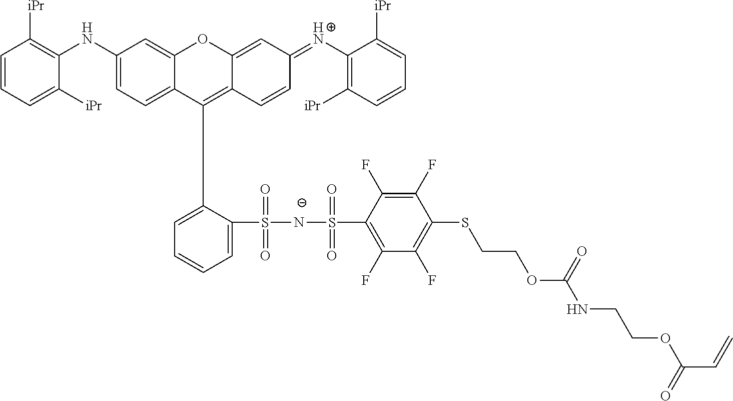

A-5: cyclohexanone solution (solid content: 12.3 mass %) of a dye having the following structure (dye having a triarylmethane coloring agent structure, molecular weight: 1165.32)

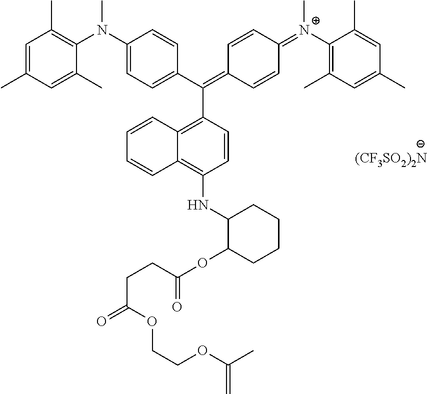

A-6: cyclohexanone solution (solid content: 12.3 mass %) of a dye having the following structure (cyan dye having a cyanine coloring agent structure; molecular weight: 774.97)

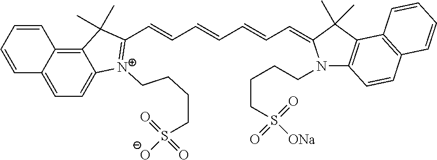

A-7: cyclohexanone solution (solid content: 12.3 mass %) of a dye having the following structure (cyan dye having a squarylium coloring agent structure; molecular weight: 410.52)

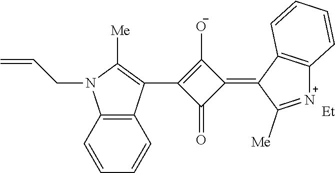 [SMILES: C=CCn1c(C)c(C2=C([O-])/C(=C3/C(C)=[NH+]c4ccccc43)C2=O)c2ccccc21]

A-8: cyclohexanone solution (solid content: 12.3 mass %) of C. I. Acid Red 289 (magenta dye having a xanthene coloring agent structure; molecular weight: 676.73)

(Pigment Dispersion Liquid)

Dispersion Liquids 1 to 9: dispersion liquids 1 to 9 described above

(Photopolymerization Initiator)

I-2: Irgacure OXE02 (manufactured by BASF)

I-3 to I-6: compounds having the following structures

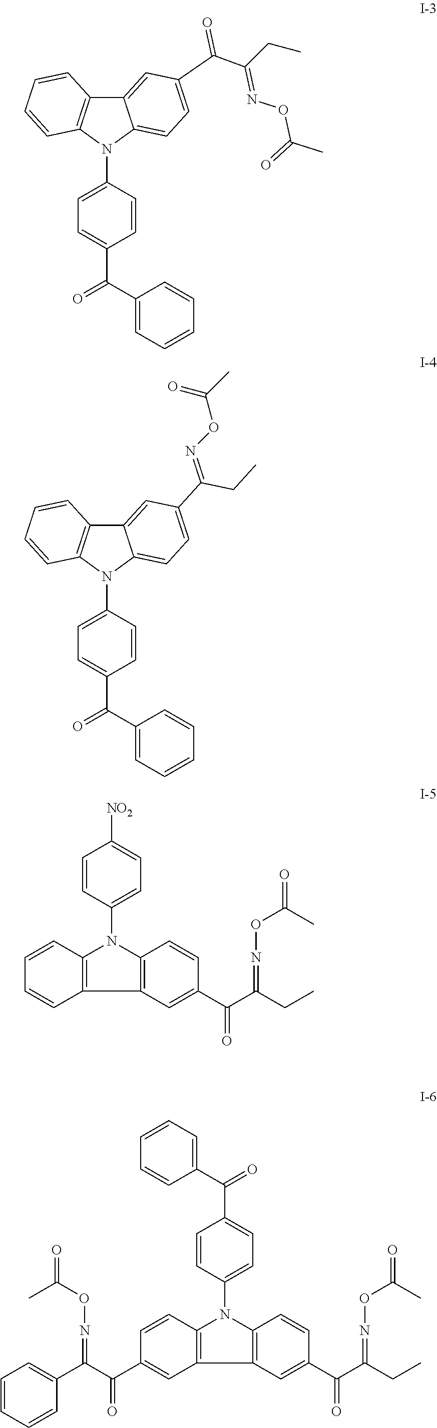

(Polymerizable Compound)

M-1: dipentaerythritol hexaacrylate (NK ESTER A-DPH-12E, manufactured by Shin-Nakamura Chemical Co., Ltd.)

M-2: compound having the following structure

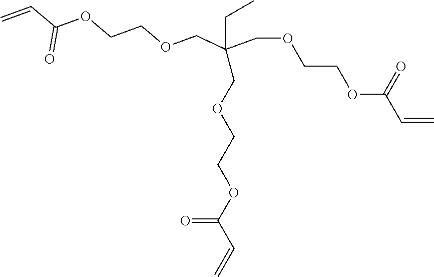 [SMILES: C=CC(=O)OCCOCC(CC)(COCCOC(=O)C=C)COCCOC(=O)C=C]

M-3: compound having the following structure

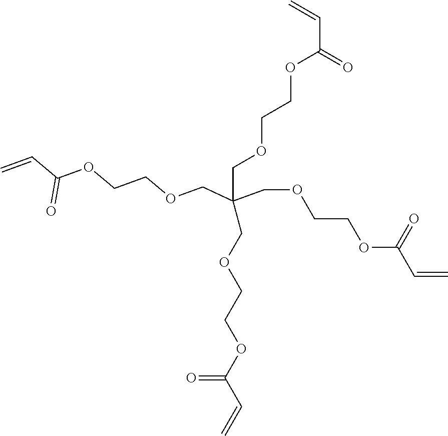 [SMILES: C=CC(=O)OCCOCC(COCCOC(=O)C=C)(COCCOC(=O)C=C)COCCOC(=O)C=C]

M-4: compound having the following structure

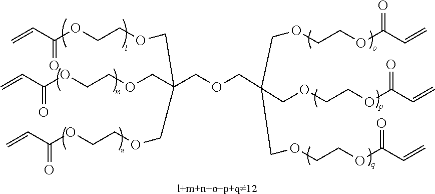

(Specific Compound)

A salt of an anion and a cation of the types described in the tables above:

each specific compound was dissolved in methanol to prepare a solution for measurement, and in a case where the absorbance of this solution at 25° C. was measured using a cell having an optical path length of 1 cm, the specific absorbance at the maximum absorption wavelength in a wavelength range of 400 to 700 nm, which is represented by Expression (A_{λ}) described above, was all 5 or less. In addition, the amount of each specific compound dissolved in 100 g of cyclohexanone at 25° C. was all 0.1 g or more. A structure of a cation E101 and structures of anions AN1, AN2, AN7, AN11, AN15, AN18, AN21, AN22, AN23, AN24, AN25, AN26, AN27, AN28, AN29, AN30, AN31, AN32, AN37, and AN39 are shown below. The pKa of conjugate acids of these anions was all 0 or less.

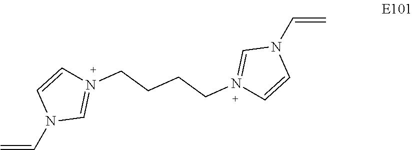

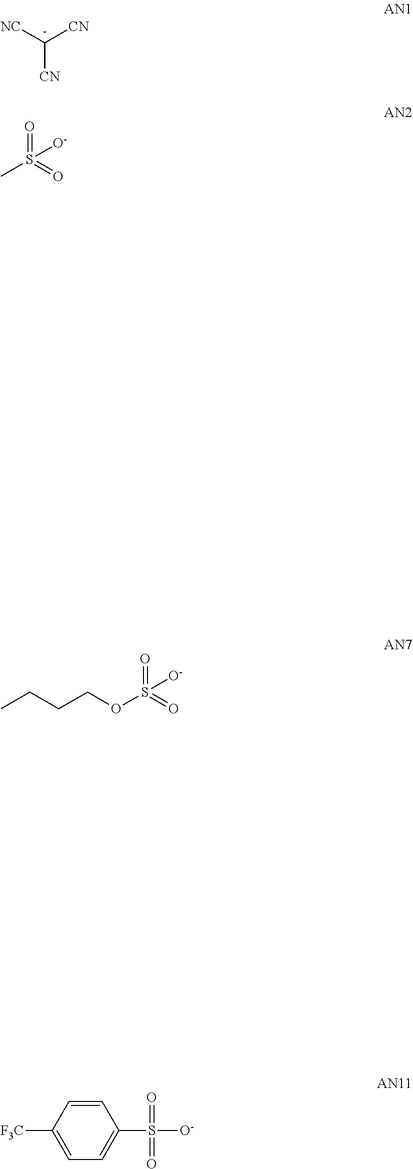

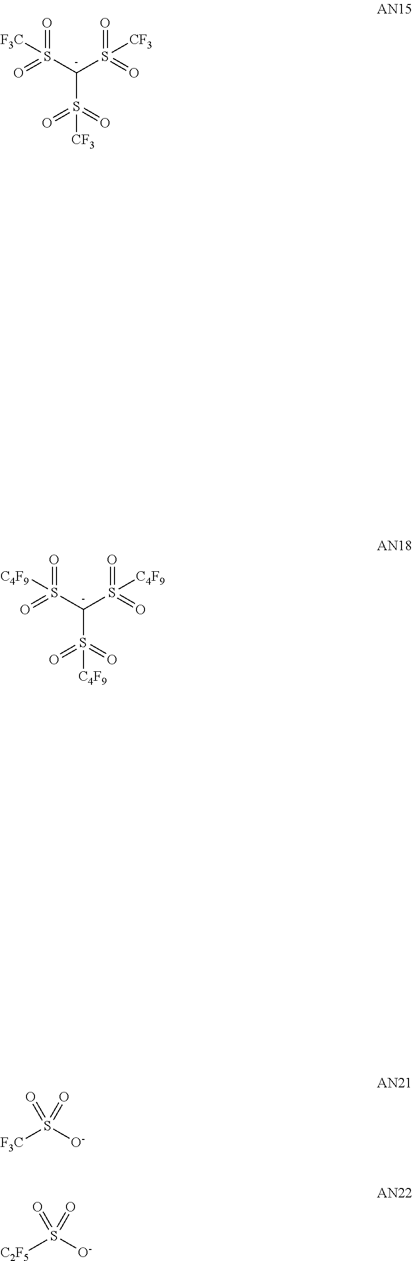

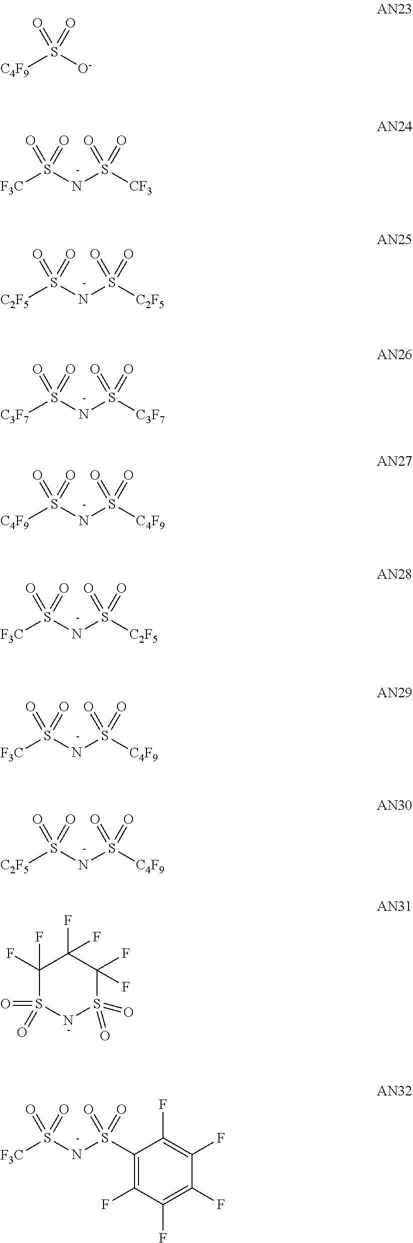

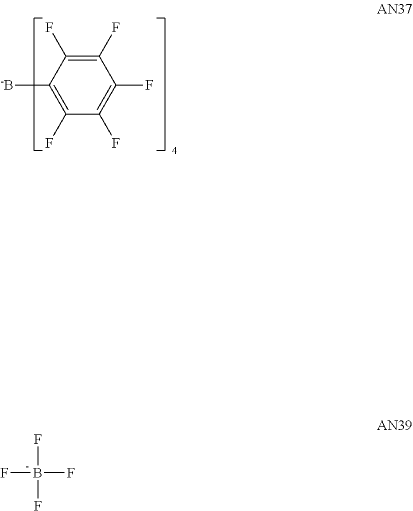

(Resin)

P-1: 30 mass % of propylene glycol monomethyl ether acetate (PGMEA) solution of a resin having the following structure (the numerical value described together with the main chain indicates a molar ratio of the repeating unit; weight-average molecular weight: 11000, resin including an acid group)

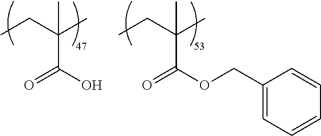

P-2: 40 mass % of PGMEA solution of a resin having the following structure (the numerical value described together with the main chain indicates a molar ratio of the repeating unit; weight-average molecular weight: 11000, resin including an acid group)

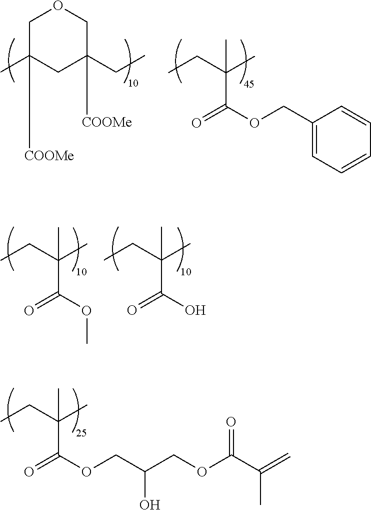

(Thermosetting Agent)

T-1: compound having the following structure

T-2: compound having the following structure

T-3: compound having the following structure

T-4: compound having the following structure (weight-average molecular weight: 9000)

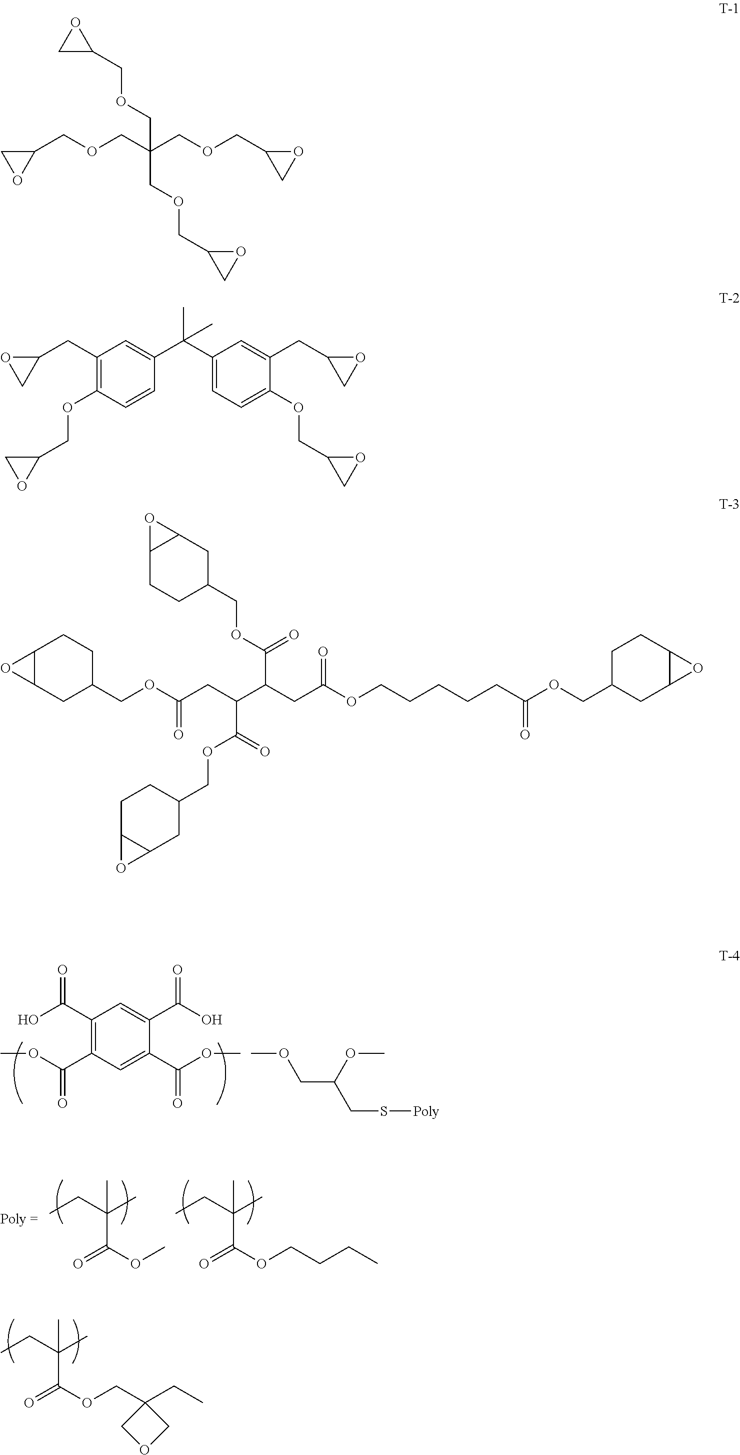

<Performance Evaluation>

(Evaluations of Chipping, Developability, and Adhesiveness)

A silicon wafer having a diameter of 8-inch (20.32 cm) was coated with a composition for forming a base layer (CT-4000L, manufactured by FUJIFILM Electronic Materials Co., Ltd.) by using a spin coater so that the thickness after post-baking was 0.1 μm, and then a base layer was formed by heating the silicon wafer at 220° C. for 300 seconds using a hot plate to obtain a silicon wafer with a base layer.

Each photosensitive composition was applied to the silicon wafer with a base layer using a spin coater so that a film thickness after post-baking was 0.5 μm, and using a hot plate, the photosensitive composition was heated at 100° C. for 2 minutes to obtain a composition layer.

Next, using an i-ray stepper exposure device FPA-3000 i5+(manufactured by Canon Corporation), the composition layer was exposed with light having a wavelength of 365 nm and an exposure amount of 1000 mJ/cm² through a mask having a dot pattern of 1.0 μm square. Next, the silicon wafer on which the exposed coating film was formed was placed on a horizontal rotary table of a spin-shower developing machine (DW-30 Type, manufactured by Chemitronics Co., Ltd.), and subjected to a puddle development at 23° C. for 60 seconds using a 60% diluted solution of CD-2000 (manufactured by Fujifilm Electronic Materials Co., Ltd.) as a developer. Thereafter, the silicon wafer was fixed on the horizontal rotary table by a vacuum chuck method, a rinse treatment was performed by supplying pure water from an ejection nozzle from above a rotation center in shower-like while rotating the silicon wafer at a rotation speed of 50 rpm by a rotation device, and then the silicon wafer was spray-dried. Furthermore, a heating treatment (post-baking) was performed for 300 seconds using a hot plate at 200° C. to form a pixel (colored pattern).

The silicon wafer on which the pixel was formed was observed with a scanning electron microscope (SEM) (magnification: 10000 times) to evaluate chipping and developability according to the following evaluation standard.

In addition, the silicon wafer on which the pixel was formed was observed using an optical microscope, and among all pixels, the number of pixels closely attached to the silicon wafer were counted to evaluate adhesiveness.

˜Evaluation Standard of Chipping˜

A: no chipping was found on edges of the pixel.

B. very few chipping was found on edges of the pixel, but there was no problem in practical use.

C: few chipping was found on edges of the pixel, but there was no problem in practical use.

D: chipping was remarkably found on edges of the pixel.

˜Evaluation Standard of Developability˜

A: no residue was found outside a region where the pixel was formed (non-exposed portion).

B: very small amount of residue was found outside a region where the pixel was formed (non-exposed portion), but there was no problem in practical use.

C: small amount of residue was found outside a region where the pixel was formed (non-exposed portion), but there was no problem in practical use.

D: residue was remarkably found outside a region where the pixel was formed (non-exposed portion).

˜-Evaluation Standard of Adhesiveness˜

A: all pixels were closely attached with each other.

B: pixels closely attached with each other were 98% or more and less than 100% of all pixels.

C: pixels closely attached with each other were 95% or more and less than 98% of all pixels.

D: pixels closely attached with each other were less than 95% of all pixels.

(Evaluation of Heat Resistance)

A glass substrate was coated with a composition for forming a base layer (CT-4000L, manufactured by FUJIFILM Electronic Materials Co., Ltd.) by using a spin coater so that the thickness after post-baking was 0.1 μm, and then a base layer was formed by heating the glass substrate at 220° C. for 1 hour using a hot plate to obtain a glass substrate with a base layer. Each photosensitive composition was applied to the glass substrate with a base layer using a spin coater so that a film thickness after post-baking was 0.5 μm, and using a hot plate, the photosensitive composition was heated at 100° C. for 2 minutes to obtain a composition layer. The composition layer was exposed to light having a wavelength of 365 nm by irradiating the composition layer with an exposure amount of 500 mJ/cm². Next, post-baking was performed at 220° C. for 300 seconds using a hot plate to obtain a film. Light transmittance (transmittance) of the obtained film in a wavelength range of 400 to 700 nm was measured by using MCPD-3000 manufactured by OTSUKA ELECTRONICS Co., LTD. Next, the film produced above was heated at 265° C. for 5 minutes. The transmittance of the film after heating was measured, the maximum value of variation of transmittance was determined, and then the heat resistance was evaluated based on the following standard. In addition, the measurement of transmittance was performed 5 times for each sample, and the average value of the 3 times result except the maximum value and the minimum value was adopted. In addition, the maximum value of the variation of transmittance means a variation of transmittance of the film in a wavelength which has the largest variation of transmittance in a range of 400 to 700 nm before and after heating.

A: maximum value of variation of transmittance was 1% or less.

B: maximum value of variation of transmittance was more than 1% and 1.5% or less.

C: maximum value of variation of transmittance was more than 1.5% and 2.0% or less.

D: maximum value of variation of transmittance was more than 2.0%.

TABLE 8

| | Performance | | | |
|---|---|---|---|---|
| | | | | Heat |
| | Chipping | Adhesiveness | Developability | resistance |
| Example 1 | C | C | B | B |
| Example 2 | C | C | B | A |
| Example 3 | C | C | B | A |
| Example 4 | C | B | B | A |
| Example 5 | C | B | B | A |
| Example 6 | C | B | B | A |
| Example 7 | B | B | A | A |
| Example 8 | B | B | A | A |
| Example 9 | B | B | A | A |
| Example 10 | B | B | A | A |
| Example 11 | B | B | A | A |
| Example 12 | B | B | A | A |
| Example 13 | B | B | A | A |
| Example 14 | B | B | A | A |
| Example 15 | B | B | A | A |
| Example 16 | B | B | A | A |
| Example 17 | B | B | A | A |
| Example 18 | B | B | A | A |
| Example 19 | A | B | A | A |
| Example 20 | A | B | A | A |
| Example 21 | A | B | A | A |
| Example 22 | A | B | A | A |
| Example 23 | A | B | A | A |
| Example 24 | A | A | A | A |
| Example 25 | A | A | A | A |
| Example 26 | A | A | A | A |
| Example 27 | A | A | A | A |
| Example 28 | A | A | A | A |
| Example 29 | A | A | A | A |
| Example 30 | A | A | A | A |
| Example 31 | A | A | A | A |
| Example 32 | A | A | A | A |
| Example 33 | A | A | A | A |
| Example 34 | A | A | A | A |
| Example 35 | A | A | A | A |
| Example 36 | A | A | A | A |
| Example 37 | A | A | A | A |
| Example 38 | A | A | A | A |
| Example 39 | A | A | A | A |
| Example 40 | A | A | A | A |

TABLE 9

| | Performance | | | |
|---|---|---|---|---|
| | | | | Heat |
| | Chipping | Adhesiveness | Developability | resistance |
| Example 41 | A | A | A | A |
| Example 42 | A | A | A | A |
| Example 43 | C | B | A | A |
| Example 44 | C | B | A | A |
| Example 45 | B | B | A | A |
| Example 46 | B | B | A | A |
| Example 47 | B | B | A | A |
| Example 48 | A | B | A | A |
| Example 49 | A | B | A | A |
| Example 50 | A | B | A | A |
| Example 51 | A | B | A | A |
| Example 52 | B | A | A | A |
| Example 53 | A | A | A | A |
| Example 54 | A | A | A | A |
| Example 55 | A | A | A | A |
| Example 56 | B | A | A | A |
| Example 57 | B | A | A | A |
| Example 58 | A | A | A | A |
| Example 59 | A | A | A | A |
| Example 60 | A | A | A | A |
| Example 61 | B | A | A | A |
| Example 62 | A | B | B | C |
| Example 63 | A | B | B | B |
| Example 64 | A | A | A | A |
| Example 65 | A | B | B | A |
| Example 66 | A | B | B | A |
| Example 67 | A | B | B | A |
| Example 68 | A | B | B | A |
| Example 69 | A | B | B | C |
| Example 70 | A | B | B | C |
| Example 71 | A | B | B | C |
| Example 72 | A | A | A | A |
| Example 73 | A | A | A | A |
| Example 74 | A | A | A | A |
| Example 75 | A | A | A | A |
| Example 76 | B | A | A | A |
| Example 77 | A | A | A | A |
| Example 78 | A | A | A | A |
| Example 79 | A | A | A | A |
| Example 80 | B | A | A | A |

TABLE 10

| | Performance | | | |
|---|---|---|---|---|
| | | | | Heat |
| | Chipping | Adhesiveness | Developability | resistance |
| Example 81 | A | A | A | A |
| Example 82 | A | A | A | A |
| Example 83 | A | A | A | A |
| Example 84 | A | A | A | A |
| Example 85 | A | A | A | A |
| Example 86 | A | A | A | A |
| Example 87 | A | A | A | A |
| Example 88 | A | A | A | A |
| Example 89 | A | A | A | A |
| Example 90 | A | A | A | A |
| Example 91 | A | A | A | A |
| Example 92 | A | A | A | A |
| Example 93 | A | A | A | A |
| Example 94 | C | C | B | A |
| Example 95 | A | A | A | A |
| Example 96 | A | A | A | A |
| Example 97 | A | A | A | A |
| Example 98 | A | A | A | A |
| Example 99 | A | A | A | A |
| Example 100 | A | A | A | A |
| Example 101 | A | A | A | A |
| Example 102 | A | A | A | A |
| Example 103 | A | A | A | A |
| Example 104 | A | A | A | A |
| Comparative | D | D | D | D |
| Example 1 | | | | |
| Comparative | D | D | C | C |
| Example 2 | | | | |
| Comparative | D | D | C | C |
| Example 3 | | | | |

As shown in the above tables, Examples had better evaluation of chipping than Comparative Examples. Further, in Examples, the evaluations of adhesiveness, developability, and heat resistance were also good.

### Example 1001

A silicon wafer was coated with a green photosensitive composition by a spin coating method so that the thickness of a film after film formation was 1.0 μm. Next, the composition was heated using a hot plate at 100° C. for 2 minutes. Next, using an i-ray stepper exposure device FPA-3000 i5+(manufactured by Canon Inc.), exposure was performed with light having an exposure amount of 1000 md/cm² through a mask having a dot pattern of 2 μm square. Next, puddle development was performed at 23° C. for 60 seconds using a 0.3 mass % of tetramethylammonium hydroxide (TMAH) aqueous solution. Next, the coating film was rinsed by spin showering and was cleaned with pure water. Next, the green photosensitive composition was patterned by heating at 200° C. for 5 minutes using a hot plate to form a green pixel. In the same process, a red photosensitive composition and a blue photosensitive composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the red photosensitive composition, the photosensitive composition of Example 104 was used. As the blue photosensitive composition, the photosensitive composition of Example 34 was used. As the green photosensitive composition, the photosensitive composition of Example 70 was used.

What is claimed is:

1. A photosensitive composition comprising:
a colorant A;
a photopolymerization initiator B;
a polymerizable compound C; and
a compound D which is a salt of an anion and a di- or higher valent cation having a formula weight or molecular weight of 1000 or less and has a specific absorbance of 5 or less, the specific absorbance being represented by Expression (A_{λ}) at a maximum absorption wavelength in a wavelength range of 400 to 700 nm,
E¹=A¹/(c¹×l¹) . . . (A_{λ})
in Expression (A_{λ}), E¹ represents the specific absorbance of the compound D at the maximum absorption wavelength in the wavelength range of 400 to 700 nm,
A¹ represents an absorbance of the compound D at the maximum absorption wavelength in the wavelength range of 400 to 700 nm,
l¹ represents a cell length in units of cm, and
c¹ represents a concentration of the compound D in a solution in units of mg/ml.

2. The photosensitive composition according to claim 1,
wherein the cation of the compound D is a di- or higher valent metal cation.

3. The photosensitive composition according to claim 2,
wherein the di- or higher valent metal cation is a magnesium cation, an aluminum cation, a calcium cation, a scandium cation, a titanium cation, a vanadium cation, a chromium cation, a manganese cation, an iron cation, a cobalt cation, a nickel cation, a copper cation, a zinc cation, a gallium cation, a strontium cation, a barium cation, a hafnium cation, a radium cation, or a cation of a rare earth element.

4. The photosensitive composition according to claim 1,
wherein the cation of the compound D is a magnesium cation, a calcium cation, a copper cation, a zinc cation, a strontium cation, a lanthanum cation, a cerium cation, or a neodymium cation.

5. The photosensitive composition according to claim 1,
wherein the anion of the compound D has at least one selected from a fluorine atom or a sulfur atom.

6. The photosensitive composition according to claim 1,
wherein a pKa of a conjugate acid of the anion of the compound D is 0 or less.

7. The photosensitive composition according to claim 1,
wherein the anion of the compound D is a sulfonate anion having a fluorine atom, a sulfate anion, a sulfonimide anion, or a sulfomethide anion.

8. The photosensitive composition according to claim 1,
wherein the anion of the compound D is an anion represented by Formula (1) or Formula (2), 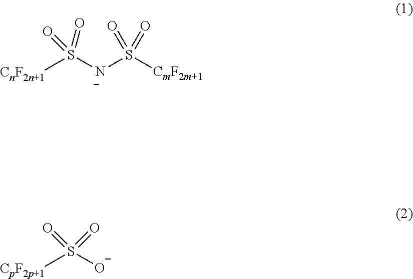
in the formulae, n, m, and p each independently represent an integer of 1 or more.

9. The photosensitive composition according to claim 1,
wherein an amount of the compound D dissolved in 100 g of cyclohexanone at 25° C. is 0.1 g or more.

10. The photosensitive composition according to claim 1,
wherein the compound D is included in an amount of 1 to 5 mass % in a total solid content of the photosensitive composition.

11. The photosensitive composition according to claim 1,
wherein the colorant A includes a dye.

12. The photosensitive composition according to claim 11,
wherein the dye includes a compound having a coloring agent structure selected from a xanthene coloring agent structure, a triarylmethane coloring agent structure, a cyanine coloring agent structure, a squarylium coloring agent structure, and an anthraquinone coloring agent structure.

13. The photosensitive composition according to claim 11,
wherein the dye includes at least one selected from a cyan dye, a magenta dye, or a yellow dye.

14. A film formed of the photosensitive composition according to claim 1.

15. A color filter comprising:
the film according to claim 14.

16. A solid-state imaging element comprising:
the film according to claim 14.

17. An image display device comprising:
the film according to claim 14.
